(19) United States
(12) Patent Application Publication
(10) Pub. No.: US 2026/0223362 A1
(43) Pub. Date: Jul. 30, 2026

(54) SEMICONDUCTOR STRUCTURE AND A METHOD FOR MANUFACTURING THE SAME, AND MEMORY SYSTEM

(71) Applicant: Yangtze Memory Technologies Co., Ltd., Wuhan (CN)

(72) Inventors: Zichen LIU, Wuhan (CN); Zongliang HUO, Wuhan (CN); Xiaolong DU, Wuhan (CN); Wei LIU, Wuhan (CN)

(21) Appl. No.: 19/375,495

(22) Filed: Oct. 31, 2025

(30) Foreign Application Priority Data
Jan. 24, 2025 (CN) 202510121466.5

(51) Int. Cl. H10B 12/00; H01L 23/528; H10D 1/68; H10D 30/01; H10D 30/67

(52) U.S. Cl. CPC H10B 12/488; H10B 12/02; H10B 12/315; H10B 12/482; H10B 12/50; H10D 1/716; H10D 30/0312; H10D 30/6735; H10D 30/6757; H10W 20/435

(57) ABSTRACT

Semiconductor structures, manufacturing methods, and memory systems are provided. An example semiconductor structure includes a plurality of channel structures arranged in rows and columns and a plurality of word lines. Channel structures in a row are arranged at intervals along a first direction, and the rows of channel structures are arranged at intervals along a second direction. The plurality of word lines extend along the first direction and are arranged at intervals along the second direction and each coupled to a respective row of channel structures. The plurality of word lines includes first, second, and third word lines, and the second word line is between the first word line and the third word line. The first and third word lines are respectively coupled to two adjacent channel structures in a same column of channel structures, and the second word line is coupled to another column of channel structures.

### CROSS-REFERENCE TO RELATED APPLICATIONS

This application claims priority to Chinese Patent Application No. 202510121466.5, filed on Jan. 24, 2025, which is hereby incorporated by reference in its entirety.

### TECHNICAL FIELD

The present disclosure relates to the field of semiconductor chip technology, and particularly to a semiconductor structure and a method for manufacturing the same, and a memory system.

### BACKGROUND

With the improvement of process technology, circuit design, and manufacturing processes, a dynamic random access memory (DRAM) has been scaled to a smaller size. However, as the feature size of a memory cell in a memory approaches the lower limit, planar processes and manufacturing techniques become challenging and costly, resulting in the density of memory cells approaching the upper limit.

Therefore, how to further achieve the miniaturization of DRAM has become a technical problem that is difficult for current technicians to solve.

### SUMMARY

Implementations of the present disclosure provide a semiconductor structure and a method for manufacturing the same, and a memory system.

Implementations of the present disclosure adopt the following technical solutions:

On one hand, an implementation of the present disclosure provides a semiconductor structure. The semiconductor structure comprises a plurality of channel structures and a plurality of word lines. The plurality of channel structures are arranged in a plurality of rows and columns, wherein a plurality of channel structures in a row of channel structures are arranged at intervals along a first direction, the plurality of rows of channel structures are arranged at intervals along a second direction, and the first direction intersects with the second direction. A word line extends along the first direction, and the plurality of word lines are arranged at intervals along the second direction and each coupled to a row of channel structures, wherein the plurality of word lines comprise a first word line, a second word line and a third word line, the second word line is between the first word line and the third word line, the first word line and the third word line are coupled to two adjacent channel structures in the same column of channel structures, respectively, and the second word line is coupled to another column of channel structures.

In some implementations, the semiconductor structure further comprises a plurality of bit lines. A bit line extends along the first direction, and the plurality of bit lines are arranged at intervals along the second direction, wherein two adjacent columns of channel structures are connected to the same bit line.

In some implementations, a bit line is disposed at a side of a channel structure along a third direction and is connected with the ends of two adjacent columns of channel structures at the side, wherein the third direction passes through a plane where the first direction and the second direction are located.

In some implementations, a channel structure runs through a word line along a third direction, and in the third direction, the channel structure comprises a first end and a second end disposed opposite to each other, wherein the size of the first end in the second direction is less than or equal to the size of the word line in the second direction, and the size of the second end in the second direction is less than or equal to the size of the word line in the second direction. The third direction passes through a plane where the first direction and the second direction are located.

In some implementations, the size of the channel structure in the second direction is less than or equal to the size of the channel structure in the first direction.

In some implementations, in the third direction, both ends of the channel structure protrude from the word line.

In some implementations, the material of the channel structure includes an oxide semiconductor material.

In some implementations, the semiconductor structure further comprises a gate dielectric layer between the channel structure and the word line.

In some implementations, the semiconductor structure further comprises a plurality of capacitor units arranged in a plurality of rows and columns. Each capacitor unit is disposed at an end of one channel structure away from a bit line and is connected with an end of the channel structure away from the bit line, wherein in a direction parallel to a plane where the first direction and the second direction are located, the capacitor unit comprises a first side and a second side located on two sides of the channel structure in the direction, respectively.

In some implementations, the capacitor unit disposed at an end of the channel structure away from the bit line is in contact with an end of the channel structure away from the bit line.

In some implementations, the capacitor unit comprises a first electrode, a second electrode and a first dielectric layer. The first electrode extends along a third direction and is connected with an end of the channel structure away from the bit line. The second electrode surrounds at least a part of the first electrode, and the first dielectric layer is between the first electrode and the second electrode, wherein in the third direction, the size of an end of the first electrode close to the channel structure is larger than the size of an end of the first electrode away from the channel structure. The third direction passes through the plane where the first direction and the second direction are located.

In some implementations, the first direction is perpendicular to the second direction, wherein the ratio of the distance between two adjacent word lines to the distance between two adjacent capacitor units is greater than or equal to 0.25 and less than or equal to 0.9. The ratio of the distance between two adjacent bit lines to the distance between two adjacent capacitor units is greater than or equal to 0.5 and less than or equal to 1.9.

In some implementations, the semiconductor structure further comprises an interconnection layer located at a side of a memory array including the channel structure and the capacitor unit in a third direction. The interconnection layer includes a first connection structure, a second connection structure, and a third connection structure. The first connection structure is connected with the bit line, a part of the second connection structure extends into the memory array and is connected with the word line, and a part of the third connection structure extends into the memory array and is connected with the capacitor unit. Alternatively, the first connection structure is connected with the capacitor unit, a part of the second connection structure extends into the memory array and is connected with the bit line, and a part of the third connection structure extends into the memory array and is connected with the word line.

In some implementations, the semiconductor structure further comprises a peripheral device. The peripheral device is stacked on a side of the interconnect layer away from the memory array and coupled to the memory array through the interconnect layer.

On the other hand, an implementation of the present disclosure provides a manufacturing method of a semiconductor structure. The manufacturing method of the semiconductor structure comprises: forming a plurality of word lines extending along a first direction, and arranged at intervals along a second direction, wherein the first direction intersects with the second direction; and forming a plurality of channel structures arranged in a plurality of rows and columns. A plurality of channel structures in a row of channel structures are arranged at intervals along the first direction, the plurality of rows of channel structures are arranged at intervals along the second direction, and each word line is coupled to a row of channel structures, and wherein the plurality of word lines comprise a first word line, a second word line and a third word line, the second word line is between the first word line and the third word line, the first word line and the third word line are coupled to two adjacent channel structures in the same column of channel structures, respectively, and the second word line is coupled to another column of channel structures.

In some implementations, the forming the plurality of word lines comprises: forming a stack structure, wherein the stack structure comprises two first dielectric layers and a conductive layer stacked along a third direction, and the conductive layer is disposed between the two first dielectric layers, and wherein the third direction passes through a plane where the first direction and the second direction are located; and forming a plurality of strip-shaped grooves in the stack structure to separate the conductive layer into a plurality of word lines, wherein a strip-shaped groove extends along the first direction and runs through the stack structure along the third direction, and the plurality of strip-shaped grooves are arranged at intervals along the second direction.

In some implementations, before forming the plurality of channel structures, the manufacturing method of the semiconductor structure further comprises: forming a plurality of first through-holes in the stack structure, wherein a first through-hole runs through the stack structure along the third direction, and the plurality of first through-holes are arranged in a plurality of rows and columns, a plurality of first through-holes in a row of first through-holes are arranged at intervals along the first direction, and the plurality of rows of first through-holes are arranged at intervals along the second direction, and wherein the strip-shaped groove is formed between two adjacent rows of first through-holes.

In some implementations, the forming the plurality of channel structures comprises: forming a semiconductor material within the first through-holes to form the channel structures.

In some implementations, before forming the channel structures, the manufacturing method of the semiconductor structure further comprises: forming a gate dielectric layer on a sidewall of a first through-hole.

In some implementations, the manufacturing method of the semiconductor structure further comprises: forming a bit line. The bit line is formed at an end of a channel structure along a third direction, extends along the second direction, and is connected with the ends of two adjacent columns of channel structures, wherein the third direction passes through a plane where the first direction and the second direction are located.

In yet another aspect, implementations of the present disclosure provide a memory system, comprising: a semiconductor structure as the semiconductor structure mentioned above; and a controller coupled to the semiconductor structure to control the semiconductor structure to store data.

### BRIEF DESCRIPTION OF THE DRAWINGS

In order to provide a clearer explanation of the technical solution of the present disclosure, a brief introduction will be given to the accompanying drawings required for some implementations of the present disclosure. It will be apparent that the accompanying drawings described below are only for some implementations of the present disclosure. For those skilled in the art, other drawings may be obtained based on these drawings. Moreover, the accompanying drawings in the following description may be regarded as schematic diagrams and are not limitations on the actual size of products, the actual process of methods, the actual timing of signals, etc. involved in implementations of the present disclosure.

FIG. 1 is a structural block diagram of an electronic device provided in some implementations of the present disclosure;

FIG. 2 is a structural block diagram of a memory provided in some implementations of the present disclosure;

FIG. 3 is a schematic diagram of a film layer of a semiconductor structure in the context of a GAA transistor, provided by some implementations of the present disclosure;

FIG. 4 is a structural schematic diagram of a semiconductor structure in the context of a GAA transistor, provided by some implementations of the present disclosure;

FIG. 5 is a schematic diagram of a film layer of a semiconductor structure in the context of a CAA transistor, provided by some implementations of the present disclosure;

FIG. 6 is a structural schematic diagram of a semiconductor structure in the context of a CAA transistor, provided by some implementations of the present disclosure;

FIG. 7 is a structural schematic diagram of a semiconductor structure in the context of another GAA transistor, provided by some implementations of the present disclosure;

FIG. 8 is a structural schematic diagram of a semiconductor structure in the context of another CAA transistor, provided by some implementations of the present disclosure;

FIG. 9 is a schematic diagram of a film layer of a semiconductor structure in the context of yet another CAA transistor, provided by some implementations of the present disclosure;

FIG. 10 is a schematic diagram of a film layer of a semiconductor structure in the context of another GAA transistor, provided by some implementations of the present disclosure;

FIG. 11 is a schematic diagram of a film layer of a semiconductor structure in the context of another CAA transistor, provided by some implementations of the present disclosure;

FIG. 12 is a schematic diagram of a film layer of yet another semiconductor structure provided by some implementations of the present disclosure;

FIG. 13 is a structural schematic diagram of a semiconductor structure in the context of yet another GAA transistor, provided by some implementations of the present disclosure;

FIG. 14 is a structural schematic diagram of a semiconductor structure in the context of yet another CAA transistor, provided by some implementations of the present disclosure;

FIG. 15 is a flowchart of a manufacturing method of a semiconductor structure in the context of a GAA transistor, provided in some implementations of the present disclosure;

FIG. 16 is a flowchart of a manufacturing method of a word line in the context of a GAA transistor, provided by some implementations of the present disclosure;

FIG. 17 is a structural schematic diagram of a semiconductor structure corresponding to the manufacturing method in FIG. 16;

FIG. 18 is a structural schematic diagram of another semiconductor structure corresponding to the manufacturing method in FIG. 16;

FIG. 19 is a schematic diagram of a film layer corresponding to the semiconductor structure in FIG. 18;

FIG. 20 is a schematic diagram of another film layer corresponding to the semiconductor structure in FIG. 18;

FIG. 21 is a structural schematic diagram of a semiconductor structure corresponding to a manufacturing method, provided in implementations of the present disclosure;

FIG. 22 is a structural schematic diagram of another semiconductor structure corresponding to a manufacturing method, provided in implementations of the present disclosure;

FIG. 23 is a structural schematic diagram of yet another semiconductor structure corresponding to a manufacturing method, provided in implementations of the present disclosure;

FIG. 24 is a flowchart of a manufacturing method of a semiconductor structure in the context of a CAA transistor, provided by some implementations of the present disclosure;

FIG. 25 is a flowchart of a manufacturing method of a word line in the context of a CAA transistor, provided by some implementations of the present disclosure;

FIG. 26 is a structural schematic diagram of a semiconductor structure corresponding to the manufacturing method in FIG. 25;

FIG. 27 is a structural schematic diagram of another semiconductor structure corresponding to the manufacturing method in FIG. 25;

FIG. 28 is a structural schematic diagram of yet another semiconductor structure corresponding to the manufacturing method in FIG. 25;

FIG. 29 is a flowchart of a manufacturing method of a channel structure in the context of a CAA transistor, provided in some implementations of the present disclosure;

FIG. 30 is a structural schematic diagram of a semiconductor structure corresponding to the manufacturing method in FIG. 29;

FIG. 31 is a schematic diagram of a film layer of a semiconductor structure corresponding to the manufacturing method in FIG. 29;

FIG. 32 is a structural schematic diagram of another semiconductor structure corresponding to the manufacturing method in FIG. 29;

FIG. 33 is a schematic diagram of a film layer corresponding to the semiconductor structure in FIG. 32;

FIG. 34 is a structural schematic diagram of yet another semiconductor structure corresponding to a manufacturing method, provided in implementations of the present disclosure;

FIG. 35 is a flowchart of a manufacturing method of a gate dielectric layer in the context of a CAA transistor, provided by some implementations of the present disclosure;

FIG. 36 is a structural schematic diagram of yet another semiconductor structure corresponding to a manufacturing method, provided in implementations of the present disclosure;

FIG. 37 is a structural schematic diagram of yet another semiconductor structure corresponding to a manufacturing method, provided in implementations of the present disclosure; and

FIG. 38 is a structural schematic diagram of yet another semiconductor structure corresponding to a manufacturing method, provided in implementations of the present disclosure.

### DETAILED DESCRIPTION

The following will provide a clear and complete description of the technical solutions in some implementations of the present disclosure, in connection with the accompanying drawings. Obviously, the described implementations are only a part of implementations of the present disclosure, and not all of them. Based on the implementations provided in the present disclosure, all other implementations obtained by those skilled in the art are within the scope of the present disclosure.

Unless otherwise required by the context, the term “including” shall be interpreted throughout the specification and claims as open and inclusive, meaning “including, but not limited to”. In the description of the specification, terms such as “one implementation”, “some implementations”, “exemplary implementations”, “exemplarily” or “some examples”, etc. are intended to indicate that specific features, structures, materials or characteristics related to the implementation or example are included in at least one implementation or example of the present disclosure. The schematic representation of the above terms does not necessarily refer to the same implementation or example. Moreover, the specific features, structures, materials, or characteristics described may be included in any one or more implementations or examples in any appropriate manner.

Below, terms “first” and “second” are only used for descriptive purposes and should not be understood as indicating or implying relative importance or implying the number of technical features indicated. Thus, the features limited with “first” and “second” may explicitly or implicitly include one or more of these features. In the description of implementations of the present disclosure, the meaning of “a plurality of” refers to two or more, unless otherwise specified.

When describing some implementations, expressions such as “couple” and “connect” and their derivatives may be used. For example, in describing some implementations, the term “connect” may be used to indicate that two or more components have direct physical or electrical contact with each other. As another example, in describing some implementations, the term “couple” may be used to indicate that two or more components have direct physical or electrical contact. However, the term ‘couple’ may also refer to two or more components that do not have direct contact with each other but still cooperate or interact with each other. The implementations disclosed here are not necessarily limited to the present disclosure.

The present disclosure describes exemplary implementations with reference to cross-sectional and/or plan views as idealized exemplary drawings. In the attached drawings, the thickness of layers and regions has been enlarged for clarity. Therefore, it may be contemplated that there may be variations in the shape relative to the drawings due to, for example, manufacturing techniques and/or tolerances. Therefore, the exemplary implementations should not be interpreted as limited to the shapes of regions shown herein, but rather include shape deviations caused by, for example, manufacturing. For example, etched areas shown as rectangles typically have curved features. Therefore, the areas shown in the drawings are essentially illustrative, and their shapes are not intended to show the actual shapes of regions of a device, and are not intended to limit the scope of the exemplary implementations.

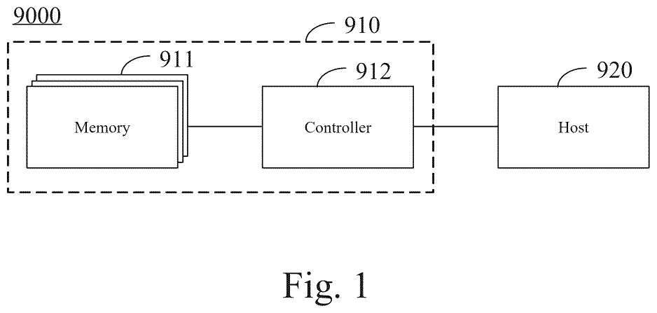

FIG. 1 is a structural block diagram of an electronic device 9000 provided in some implementations of the present disclosure. The electronic device 9000 may be a mobile phone, desktop computer, laptop, tablet, vehicle computer, game console, printer, positioning device, wearable electronic device (such as smartwatch, smart bracelet, smart glasses, etc.), smart sensor, virtual reality (VR) device, augmented reality (AR) device, or any other suitable electronic device with storage therein.

As shown in FIG. 1, electronic device 9000 may include a memory system 910 and a host 920, wherein the memory system 910 may be integrated into various types of memory devices, such as a memory card. The memory card includes any of a PC card (PCMCIA, Personal Computer Memory Card International Association), compact flash (CF) card, smart media (SM) card, memory stick, multimedia card (MMC), secure digital memory card (SD) card, and universal flash storage (UFS). That is to say, the memory system 910 may be applied and packaged into different types of electronic products.

Host 920 may include a processor of electronic device 9000, such as a central processing unit (CPU), or a system on chip (SOC), such as an application processor (AP). Host 920 may be configured to send data to or receive data from a memory.

In some implementations, memory system 910 may have one or more memories 911 and controllers 912. For example, controller 912 may be configured to operate in low duty cycle environments, such as SD cards, CF cards, universal serial bus (USB) flash drives, or other media used in electronic devices such as personal calculators, digital cameras, mobile phones, etc. Alternatively, in some other examples, controller 912 is configured to operate in high duty cycle environments such as SSD or eMMC, which are used as data storage for mobile devices such as smartphones, tablets, laptops, etc. and enterprise storage arrays. Alternatively, in some examples, the controller 912 is coupled to the memory 911 and the host 920, and configured to control data in the memory 911 while being capable of communicating with an external device (such as a host).

The number of memories 911 in memory system 910 may be one or more, as illustrated in FIG. 1 with three memories 911 as an example. Controller 912 may manage the data stored in each memory 911 and communicate with host 920. Controller 912 may be configured to control operations of each memory 911, such as read, write, and refresh operations. Controller 912 may also be configured to manage various functions related to data stored or to be stored in each memory 911, including but not limited to refresh and timing control, command/request translation, buffering and scheduling, and power management. In some implementations, controller 912 is also configured to determine the maximum memory capacity that a computer system may use, the number of memory banks, the type and speed of a memory, the depth and width of data of memory dies, and other important parameters. The controller 912 may also perform any other suitable functions. Controller 912 may communicate with an external device (such as host 920) according to a specific communication protocol. For example, controller 912 may communicate with an external device according to at least one of various interface protocols, such as USB protocol, MMC protocol, peripheral component interconnection (PCI) protocol, PCI express (PCI-E) protocol, advanced technology attachment (ATA) protocol, serial ATA protocol, parallel ATA protocol, small computer small interface (SCSI) protocol, enhanced small disk interface (ESDI) protocol, integrated drive electronics (IDE) protocol, FireWire protocol, etc.

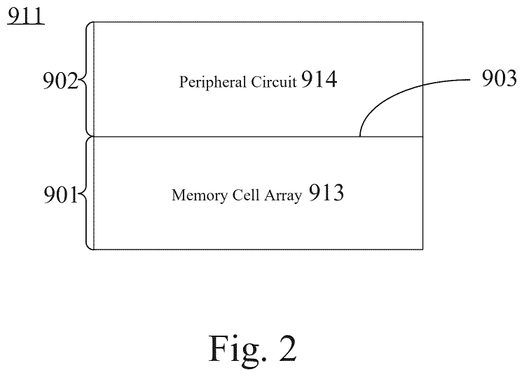

FIG. 2 is a structural block diagram of the memory 911 provided in some implementations of the present disclosure.

As shown in FIG. 2, the memory 911 includes a memory cell array 913 and a peripheral circuit 914 for controlling the memory cell array 913. The peripheral circuit 914 may include any suitable digital, analog, and/or mixed signal circuits for facilitating operations of the memory cell array 913. For example, the peripheral circuit 914 may include one or more of a page buffer, decoder (such as row decoder and column decoder), sense amplifier, driver (such as word line driver), input/output (I/O) circuit, charge pump, voltage source or generator, current or voltage reference, any part of the afore-mentioned functional circuits (such as sub-circuits), or any active or passive components of a circuit (such as transistor, diode, resistor, or capacitor).

In an example, the peripheral circuit 914 may employ complementary metal oxide semiconductor (CMOS) technology, which may be implemented using logic processes (e.g., technology nodes such as 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.).

The memory cell array 913 and the peripheral circuit 914 may be arranged side by side in the same plane, for example, on the same wafer, that is, the memory cell array 913 and the peripheral circuit 914 may be located in the same semiconductor structure. The memory cell array 913 and peripheral circuit 914 may also be formed on different wafers and bonded together in a face-to-face manner. As shown in FIG. 2, when the memory cell array 913 and the peripheral circuit 914 are formed on different wafers and bonded together in a face-to-face manner, the memory 911 may include a first semiconductor structure 901, a second semiconductor structure 902, and a bonding interface 903 between the first semiconductor structure 901 and the second semiconductor structure 902, wherein the first semiconductor structure 901 may include the memory cell array 913, and the second semiconductor structure 902 may include the peripheral circuit 914.

In some implementations, the memory cell array 913 may be an array of memory cells using vertical transistors as switches and selection devices. For example, the memory cell array 913 may be a dynamic random access memory cell array. For ease of description, a DRAM cell array may be used to describe an example of the memory cell array 913 in the present disclosure. However, it should be understood that the memory cell array 913 is not limited to DRAM cell arrays, and may also include, for example, any other suitable type of memory cell array 913 that may use vertical transistors as switches and selection devices, such as a PCM cell array, static random access memory (SRAM) cell array, ferroelectric random access memory (FRAM) cell array, resistive memory cell array, magnetic memory cell array, spin transfer torque (STT) memory cell array, etc.

When the memory cell array 913 is a DRAM cell array, the memory cells therein are DRAM cells, which include capacitors for storing data bits as positive or negative charges, and one or more transistor structures for controlling (e.g., switching and selecting) access to the DRAM cells. In some implementations, each DRAM cell is a 1T1C cell constituted by a transistor structure and a capacitor. According to some implementations, a DRAM cell may be refreshed by the peripheral circuit 914 to maintain data.

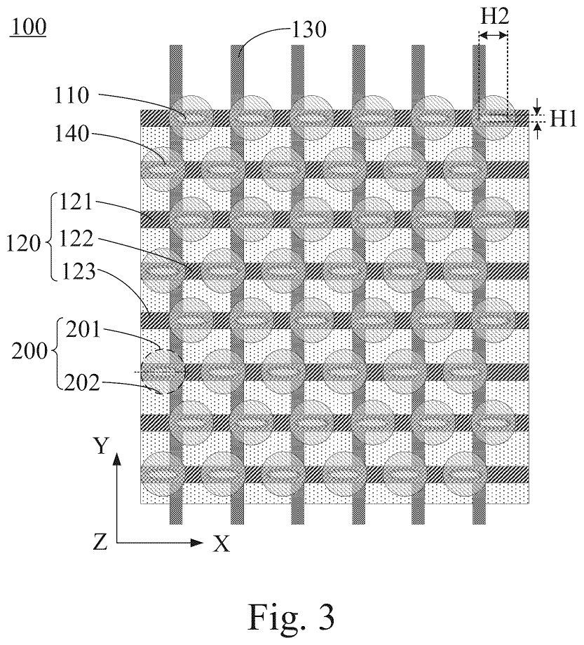

FIG. 3 is a schematic diagram of a film layer of a semiconductor structure 100 in the context of a GAA transistor, provided by some implementations of the present disclosure.

Herein, FIG. 3 is only for illustrative purposes and may not actually reflect the actual device structure (such as interconnects, etc.).

As shown in FIG. 3, in some implementations, the semiconductor structure 100 includes a plurality of channel structures 110 and a plurality of word lines 120. The plurality of channel structures 110 are arranged in a plurality of rows and columns, wherein a plurality of channel structures 110 in a row are arranged at intervals along a first direction X, the plurality of rows of channel structures 110 are arranged at intervals along a second direction Y. A word line 120 extends along the first direction X, the plurality of word lines 120 are arranged at intervals along the second direction Y and each word line 120 is coupled to a row of channel structures 110.

Herein, in an example, the word line 120 may be formed by connecting the gates corresponding to a row of channel structures 110. For example, if the materials used for the gates corresponding to a row of channel structures 110 are the same, the gates corresponding to a row of channel structures 110 may be connected into an integral structure. That is to say, structurally, there is no clear boundary between the gates corresponding to a row of channel structures 110. Based on this, as a feasible implementation, in practical applications, the region of the word line 120 corresponding to a single channel structure 110 may be used as a gate, thereby constituting a transistor structure.

Please continue to refer to FIG. 3. In the layout of semiconductor structure 100, a plurality of word lines 120 may include a first word line 121, a second word line 122, and a third word line 123, wherein the second word line 122 is between the first word line 121 and the third word line 123. The first word line 121 and the third word line 123 are coupled to two adjacent channel structures 110 in the same column, respectively, and the second word line 122 is coupled to another column of channel structures 110.

In this way, a staggered arrangement between two adjacent columns of channel structures 110 may be achieved when a plurality of channel structures 110 are arranged in a plurality of columns. That is to say, in two adjacent columns of channel structures 110, any one of channel structures 110 in a column is not adjacent to any other channel structure 110 in another column in the first direction X.

Moreover, with the development of DRAM technology, the size of a DRAM cell array is becoming smaller and smaller. For example, the size of a DRAM cell array has been reduced from 6F2 to 4F2, where F is the minimum process size of a DRAM cell. Under a 4F2 structured DRAM cell array, in order to further achieve miniaturization of a semiconductor structure, a plurality of capacitor units in the capacitor structure layer of the DRAM cell array have developed from the layout of square arrangement to the layout of hexagonal arrangement, thereby achieving the improvement of the density of capacitor units in the capacitor unit layer under the condition that the number of the capacitor units is unchanged and thus reducing the size of the capacitor structure layer.

Herein, the square arrangement refers to a plurality of capacitor units in the capacitor unit layer, wherein in the layout position, four adjacent capacitors may be arranged in a rectangular (e.g. square) shape. Hexagonal arrangement refers to a plurality of capacitor units in the capacitor unit layer, wherein in the layout position, six capacitors may be arranged in a hexagonal shape, and the number of capacitor units that may exist within the hexagon is less than or equal to 1.

Based on this, in implementations of the present disclosure, by arranging two adjacent columns of channel structures 110 in a staggered manner, a hexagonal arrangement among a plurality of channel structures 110 may be achieved when the channel structures 110 are in a plurality of columns.

In this way, the device density among a plurality of channel structures 110 may be increased and the layout area of the semiconductor structure 100 occupied by a plurality of channel structures 110 may be reduced while the number of channel structures 110 remains unchanged.

Moreover, in some examples, due to the hexagonal arrangement among a plurality of channel structures 110 in implementations of the present disclosure, a plurality of channel structures 110 may be directly manufactured on a side of the plurality of capacitor units in the third direction Z in the process of manufacturing a DRAM cell array when the layout of a plurality of capacitor units in a capacitor structure layer also adopts a hexagonal arrangement, thereby achieving the connection between the channel structures 110 and the capacitor units. That is to say, each channel structure 110 may be directly connected to a capacitor unit without the need to manufacture other connection structures (structures such as connection contacts) for transition between the two.

In this way, the semiconductor structure 100 may be simplified, and the height of the semiconductor structure 100 in the third direction Z may be reduced, thereby increasing the device density of the semiconductor structure 100 and facilitating further miniaturization of the semiconductor structure 100 in size.

Herein, in an example, the third direction Z may be the direction in which the first semiconductor structure 901 and the second semiconductor structure 902 are stacked as shown in FIG. 2, and the third direction Z may pass through the plane where the first direction X and the second direction Y are located.

Moreover, in some other examples, the layout of a plurality of capacitor units in the capacitor structure layer connected to a plurality of channel structures 110 may also adopt other forms, which is not limited by implementations of the present disclosure. Moreover, in practical applications, the connection between a plurality of channel structures 110 and a plurality of capacitor units may also be achieved through a transition structure, which is not limited by implementations of the present disclosure.

In an example, the channel structure 110 may employ semiconductor materials such as indium gallium zinc oxide (IGZO), silicon, doped silicon, germanium, or any other suitable material, which is not limited by implementations of the present disclosure. The word line 120 may employ conductive materials such as wolfram (W), cobalt (Co), copper (Cu), aluminum (Al), doped silicon, silicide, or any combination thereof. Herein, in this implementation, the material of the word line 120 may include W, and the material of the channel structure 110 may include oxide semiconductor material.

In this way, the manufactured channel structure 110 may have a smaller leakage current, thereby prolonging the data storage time of DRAM cells and reducing the device loss of the semiconductor structure 100. Moreover, since IGZO has a higher carrier mobility, under the same requirements, the size of the manufactured channel structure 110 may be reduced by using IGZO, which is beneficial for further miniaturization of the semiconductor structure 100.

Please continue to refer to FIG. 3. In some implementations, the semiconductor structure 100 further includes a plurality of bit lines 130. A bit line 130 extends along the second direction Y, and the plurality of bit lines 130 are arranged at intervals along the first direction X, wherein two adjacent columns of channel structures 110 are connected to the same bit line 130.

In this implementation, each bit line 130 may be disposed on a side of two adjacent columns of channel structures 110 along the third direction Z, and connected to an end of the two adjacent columns of channel structures 110 on the side.

Herein, in an example, in the scenario of projecting along the third direction Z, the projection of each bit line 130 may be between the projections of two adjacent columns of channel structures 110. Moreover, when there are a plurality of bit lines 130, there may be projections of two columns of channel structures 110 between projections of two adjacent bit lines 130.

In this way, when one bit line 130 is connected to two columns of channel structures 110, the distance between the bit line 130 and the two columns of channel structures 110 connected to the bit line 130 may be shortened, thereby simplifying the wiring connection structure and reducing wiring losses.

Moreover, by reasonably setting the width of the bit line 130 in the first direction X, the bit line 130 may be in contact with two adjacent channel structures 110, thereby achieving the connection between a single bit line 130 and two adjacent columns of channel structures 110, and simplifying the semiconductor structure 100, and thus reducing the height of the semiconductor structure 100 in the third direction Z and achieving further miniaturization of the semiconductor structure 100 in size.

Alternatively, in some other examples, the connection between a single bit line 130 and two columns of channel structures 110 adjacent to the bit line 130 may be achieved by setting connection structures (such as through silicon contact parts, through silicon contacts, etc.). Alternatively, the connection between the bit line 130 and the two adjacent columns of channel structures 110 may be achieved by other suitable means, which is not limited by implementations of the present disclosure.

Moreover, in this implementation, by setting a semiconductor structure in which a single bit line 130 is connected to two adjacent columns of channel structures 110, the distance between two adjacent bit lines 130 in the first direction X may be increased, thereby reducing the coupling effect (such as coupling capacitance) between the two adjacent bit lines 130 and thus improving the performance of the semiconductor structure 100.

Moreover, in such a way, the bit line 130 may be configured to control the on and off of a single transistor structure when the word line 120 is selected for a column of transistor structures, thereby enabling a single DRAM cell to perform read or write operations on data.

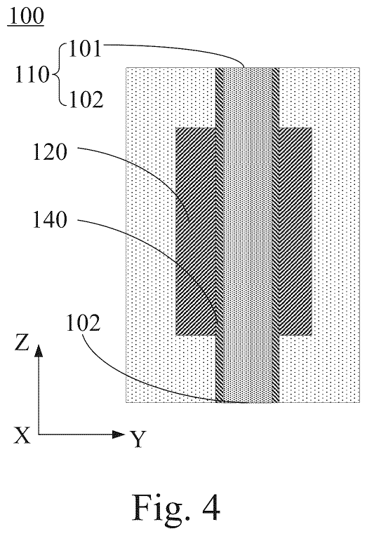

FIG. 4 is a structural schematic diagram of a semiconductor structure 100 in the context of a GAA transistor, provided by some implementations of the present disclosure.

As shown in FIGS. 3 and 4, in some implementations, the channel structure 110 runs through the word line 120 along the third direction Z, and in the third direction Z, the channel structure 110 includes a first end 101 and a second end 102 disposed opposite to each other, wherein the size of the first end 101 in the second direction X and the size of the second end 102 in the second direction X are both less than or equal to the size of the word line 120 in the second direction X. Herein, the channel structure 110 may be columnar (e.g. cylindrical, etc.), and the channel structure 110 may extend along the third direction Z to run through the word line 120.

In an example, the channel structure 110 may also take any other suitable shape, which is not limited by implementations of the present disclosure.

In this implementation, since the size of the first end 101 in the second direction X and the size of the second end 102 in the second direction X are both less than or equal to the size of the word line 120 in the second direction X, the projection of the channel structure 110 may be located inside the projection of the word line 120 when the channel structure 110 and the word line 120 are projected along the third direction Z. That is to say, in the third direction Z, the boundary of the channel structure 110 may be located inside the boundary of the word line 120, so as to realize the surrounding arrangement of the word line 120 around the channel structure 110.

In an example, if the word line 120 at the position corresponding to the channel structure 110 is used as the gate of the channel structure 110, in this scenario, the channel structure 110 and the corresponding gate may constitute a gate all around (GAA) transistor.

In this way, a voltage may be applied to the channel structure 110 through the gate to form a channel current between the source and drain of the channel structure 110, thereby achieving on/off control of the GAA transistor structure and in turn controlling the DRAM cell where the GAA transistor structure is located to read, write, or erase data.

Please continue to refer to FIG. 4. In some implementations, both ends of the channel structure 110 protrude from the word line 120 in the third direction Z.

When the transistor structure constituted by the channel structure 110 is a GAA transistor structure, both ends of the channel structure 110 in the third direction Z may protrude from the word line 120, thereby achieving the connection between the channel structure 110 and other device structures (such as capacitor units, etc.).

In this way, a connection structure between the channel structure 110 and other device structures (such as capacitor units, etc.) may be omitted, thereby simplifying the device structure and reducing the height of the semiconductor structure 100 in the third direction Z. Moreover, by arranging both ends of the channel structure 110 to protrude from the word line 120, contact between the word line 120 and the device structure connected to the channel structure 110 is avoided, thereby achieving isolation between the word line 120 and the device structure connected to the channel structure 110, and improving the stability and reliability of the semiconductor structure 100.

Please continue to refer to FIG. 4. In some implementations, the semiconductor structure 100 further includes a gate dielectric layer 140 between the channel structure 110 and the word line 120.

In this implementation, by disposing a gate dielectric layer 140 between the channel structure 110 and the word line 120, isolation between the channel structure 110 and the word line 120 may be achieved, thereby avoiding direct current conduction between the channel structure 110 and the word line 120.

In an example, the material of the gate dielectric layer 140 may include an insulating material, which may include one or more of an oxide material (such as silicon oxide), nitride material (such as silicon nitride), and oxynitride material (such as silicon oxynitride). Alternatively, the material of the gate dielectric layer 140 may also include any suitable high dielectric constant (high-K) material such as aluminum oxide, chromium oxide, zirconium oxide, etc., which is not limited by implementations of the present disclosure.

Herein, as a feasible implementation, the material of the gate dielectric layer 140 in this implementation may include aluminum oxide. In this way, the coordination between the gate dielectric layer 140 and the word line 120 may be utilized to achieve more precise control of the on or off state of the transistor structure, thereby effectively reducing the leakage current of the transistor structure and in turn improving the device performance and reliability of the semiconductor structure 100.

Please continue to refer to FIG. 3. In some implementations, since the word line 120 extends along the first direction X, in this implementation, the size H1 of the channel structure 110 in the second direction Y may be set to be less than or equal to the size H2 of the channel structure 110 in the first direction X.

In this way, the limitation of the width of the word line 120 in the second direction Y on the size of the channel structure 110 may be reduced, so that the width of the word line 120 in the second direction Y may be reduced on the basis of ensuring the performance of the semiconductor structure 100, thereby reducing the overall size of the semiconductor structure 100.

Moreover, since the word line 120 extends along the first direction X, the facing area between the channel structure 110 and the word line 120 may be increased by increasing the size H2 of the channel structure 110 in the first direction X, thereby improving the control accuracy of the word line 120 on subsequent GAA transistor structures manufactured based on the channel structure 110. Herein, in an example, a facing area may refer to the area where the projection of the channel structure 110 in the direction perpendicular to the third direction Z coincides with the projection of the word line 120 in the direction perpendicular to the third direction Z.

Moreover, in this way, the control accuracy of the word line 120 on the channel structure 110 may also be improved, the leakage current of the transistor structure manufactured based on the channel structure 110 may be reduced, thereby prolonging the retention time of DRAM cells for data.

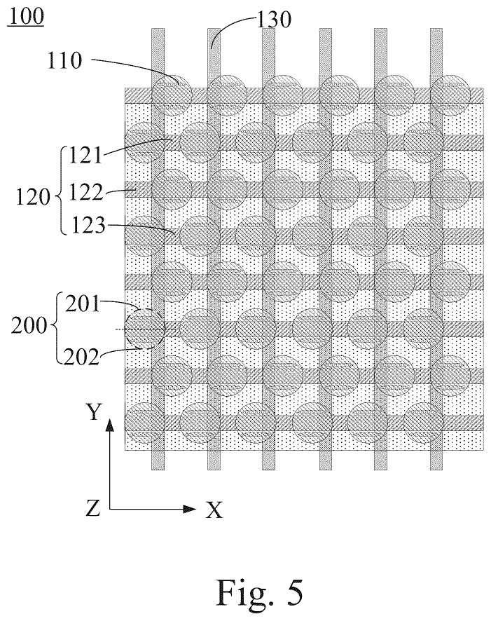

FIG. 5 is a schematic diagram of a film layer of a semiconductor structure in the context of a CAA transistor, provided by some implementations of the present disclosure.

In the afore-mentioned implementations, using the channel structure 110 and the corresponding gate to constitute a GAA transistor is described as an example. As shown in FIG. 5, in some other implementations, the channel structure 110 and the corresponding gate may also constitute a channel all around (CAA) transistor. In this scenario, at least a part of the word line 120 extends into the channel structure 110.

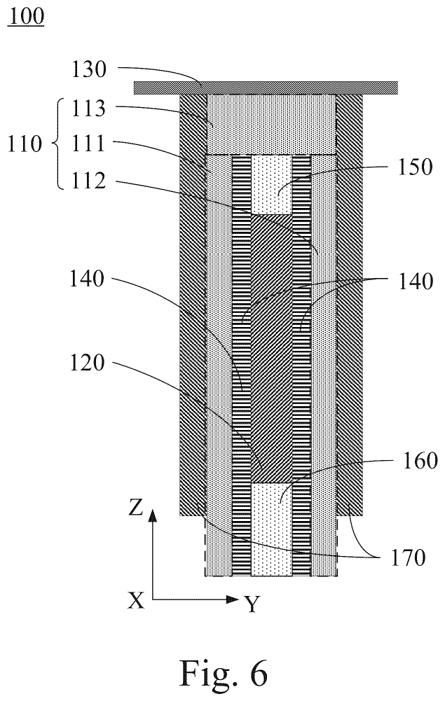

FIG. 6 is a structural schematic diagram of a semiconductor structure 100 in the context of a CAA transistor, provided by some implementations of the present disclosure.

As shown in FIG. 6, since there may be at least a part of the word line 120 within the channel structure 110, the channel structure 110 may be separated by the word line 120 into a first sub-channel 111 and a second sub-channel 112, wherein the first sub-channel 111 is disposed on a side of the word line 120 along the second direction Y, and the second sub-channel 112 is disposed on the other side of the word line 120 along the second direction Y. Herein, the first sub-channel 111 and the second sub-channel 112 both extend along the third direction Z.

In this way, the first and second sub-channels 111 and 112 may be utilized to increase the facing area between the entire channel structure 110 and the word line 120, thereby improving the control accuracy of the word line 120 on CAA transistor structures manufactured subsequently based on the channel structure 110.

Moreover, please continue to refer to FIG. 6. In some examples, the channel structure 110 may also include a connection 113. The connection 113 is disposed on a side of the bit line 130 close to the word line 120 along the third direction Z. The connection 113 extends along the second direction Y and is connected to an end of the first sub-channel 111 and an end of the second sub-channel 112.

Herein, the material of the connection 113 and the materials of the first and second sub-channels 111 and 112 may be the same or different.

In an example, when the material of the connection 113 is the same as that of the first and second sub-channels 111 and 112, the connection 113 may be connected to the first and second sub-channels 111 and 112 to form an integral structure, thereby making the channel structure 110 U-shaped. Alternatively, in some other examples, the channel structure 110 may also exhibit other morphologies, which are not limited by implementations of the present disclosure.

In this way, the connection 113 may be configured to achieve connections between the first and second sub-channels 111 and 112 and the bit line 130, thereby increasing the contact area between the channel structure 110 and the bit line 130, reducing the contact resistance between the channel structure 110 and the bit line 130, and thus reducing the device loss of the semiconductor structure 100.

Moreover, in such a way, the connection 113 may also be configured to improve the alignment accuracy between the word line 120 and the channel structure 110, thereby enhancing the electrical connection effect between the channel structure 110 and the bit line 130, and reducing the difficulty of subsequent manufacturing processes of the word line 120.

Moreover, when the transistor structure is a CAA transistor structure, the bit line may be disposed on a side of the connection 113 away from the word line 120 along the third direction Z, and connected to the connections 113 of two adjacent columns of channel structures 110.

Please continue to refer to FIG. 6. In some implementations, both ends of the first sub-channel 111 and both ends of the second sub-channel 112 protrude from the word line 120 in the third direction Z.

In this way, the first and second sub-channels 111 and 112 may be directly connected to other device structures (such as capacitor units, etc.), thereby omitting the connection structure between the first and second sub-channels 111 and 112 and other device structures, simplifying the device structure, and reducing the height of the semiconductor structure 100 in the third direction Z.

Moreover, by disposing both the first and second sub-channels 111 and 112 to protrude from the word line 120, the contact between the word line 120 and the device structures connected to the first and second sub-channels 111 and 112 may be avoided, thereby achieving isolation between the word line 120 and the device structures connected to the first and second sub-channels 111 and 112, and thus improving the stability and reliability of the semiconductor structure 100.

In some other examples, the connection between other device structures and the first and second sub-channels 111 and 112 of the channel structure 110 may also be achieved by setting connection structures (such as through silicon contact parts, through silicon contacts, etc.). Alternatively, the connection between other device structures and the first and second sub-channels 111 and 112 may be achieved by other suitable means, which is not limited by implementations of the present disclosure.

Please continue to refer to FIG. 6. In some implementations, when the channel structure 110 and the corresponding gate may also constitute a CAA transistor, the semiconductor structure 100 may further include a first sub-dielectric layer 150 and a second sub-dielectric layer 160. The first sub-dielectric layer 150 is disposed between the word line 120 and the connection 113, and the second sub-dielectric layer 160 is disposed on a side of the word line 120 away from the first sub-dielectric layer 150.

In this implementation, by disposing the first sub-dielectric layer 150 and the second sub-dielectric layer 160, isolation between the word line 120 and the connection 113 and between the word line 120 and other device structures (such as capacitor units) connected to the first and second sub-channels 111 and 112 may be achieved, avoiding the contact between the word line 120 and the connection 113 or other device structures and thereby improving the stability and reliability of the semiconductor structure 100.

Herein, in an example, the materials of the first sub-dielectric layer 150 and the second sub-dielectric layer 160 may both include insulating materials, which may include one or more of an oxide material (such as silicon oxide), nitride material (such as silicon nitride), and oxynitride material (such as silicon oxynitride), which is not limited by implementations of the present disclosure.

Please continue to refer to FIG. 6. In some implementations, when the transistor structure is CAA, the gate dielectric layer 140 may be between the first sub-channel 111 and the word line 120 and between the second sub-channel 112 and the word line 120.

In this implementation, by disposing a gate dielectric layer 140 between the first sub-channel 111 and the word line 120 and between the second sub-channel 112 and the word line 120, isolation between the channel structure 110 and the word line 120 may be achieved, thereby avoiding direct current conduction between the channel structure 110 and the word line 120.

Herein, as a feasible implementation, in the scenario of CAA transistor structure, the material of the gate dielectric layer 140 may include an insulating material, which may include one or more of an oxide material (such as silicon oxide), nitride material (such as silicon nitride), and oxynitride material (such as silicon oxynitride), which is not limited by implementations of the present disclosure. In an example, the material of the gate dielectric layer 140 in this implementation may include silicon oxide.

Moreover, please continue to refer to FIG. 6. In some examples, when the oxide semiconductor material of the channel structure 110 includes IGZO, a second dielectric layer 170 may also be disposed on a side of the first sub-channel 111 away from the word line 120, and on a side of the second sub-channel 112 away from the word line 120.

In an example, the material of the second dielectric layer 170 may include any suitable high dielectric constant (high-K) material such as aluminum oxide, chromium oxide, zirconium oxide, etc., which is not limited by implementations of the present disclosure.

In this way, the good compatibility between a high-K material and IGZO may be utilized to achieve coverage of the first and second sub-channels 111 and 112, thereby avoiding oxidation of the first and second sub-channels 111 and 112.

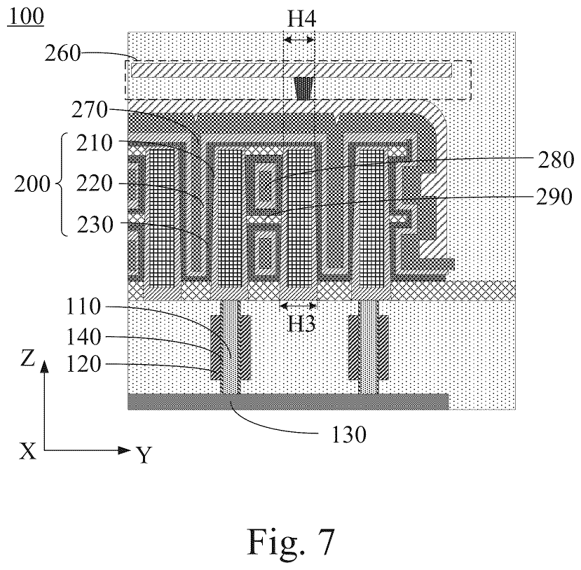

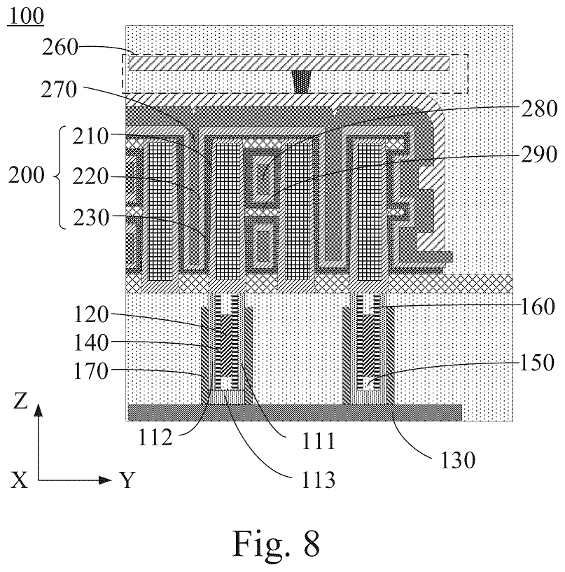

FIG. 7 is a structural schematic diagram of a semiconductor structure 100 in the context of another GAA transistor, provided by some implementations of the present disclosure, and FIG. 8 is a structural schematic diagram of a semiconductor structure 100 in the context of another CAA transistor, provided by some implementations of the present disclosure.

As shown in FIGS. 7 and 8, in some implementations, the semiconductor structure 100 may further include a plurality of capacitor units 200 arranged in a plurality of rows and columns. When the transistor structure is a GAA transistor, each capacitor unit 200 is disposed at the end of a channel structure 110 away from the bit line 130 and is connected to the end of the channel structure 110 away from the bit line 130. When the transistor structure is a CAA transistor, each capacitor unit 200 is disposed at the end of a channel structure 110 away from the bit line 130, and is connected to the end of the first sub-channel 111 away from the bit line 130 and the end of the second sub-channel 112 away from the bit line 130.

In this implementation, both ends of the channel structure 110 constituted by the first and second sub-channels 111 and 112 in the third direction Z is connected to the bit line 130 and the capacitor unit 200, respectively, to constitute a DRAM cell of 1T1C in combination with the corresponding part of the word line 120 described above. With the cooperation of the word line 120 and the bit line 130, the channel structure 110 may be configured to control the charging and discharging of the capacitor unit 200, thereby realizing the read, write or erase operations of data by the DRAM cell.

Herein, in an example, the above “connect” may include direct connection or indirect connection. In the scenario of direct connection, if the transistor structure is a GAA transistor, a capacitor unit disposed at the end of the channel structure 110 away from the bit line 130 may be in contact with the end of the channel structure 110 away from the bit line 130. If the transistor structure is a CAA transistor, a capacitor unit disposed at the end of the first and second sub-channels 111 and 112 away from the bit line 130 may be in contact with the end of the first and second sub-channels 111 and 112 away from the bit line 130.

In this way, the wiring connection structure may be simplified, thereby reducing the wiring loss of the semiconductor structure 100, and the semiconductor structure 100 may be simplified, thereby reducing the height of the semiconductor structure 100 in the third direction Z and further reducing the size of the semiconductor structure 100.

In the scenario of indirect connection, if the transistor structure is a GAA transistor, a capacitor unit disposed at the end of the channel structure 110 away from the bit line 130 may be connected to the end of the channel structure 110 away from the bit line 130 via a connection structure. If the transistor structure is a CAA transistor, a capacitor unit disposed at the end of the first and second sub-channels 111 and 112 away from the bit line 130 may be connected to the end of the first and second sub-channels 111 and 112 away from the bit line 130 via a connection structure.

In an example, the connection structure may include any suitable structure such as a through silicon contact part, a through silicon contact, etc., which is not limited by implementations of the present disclosure.

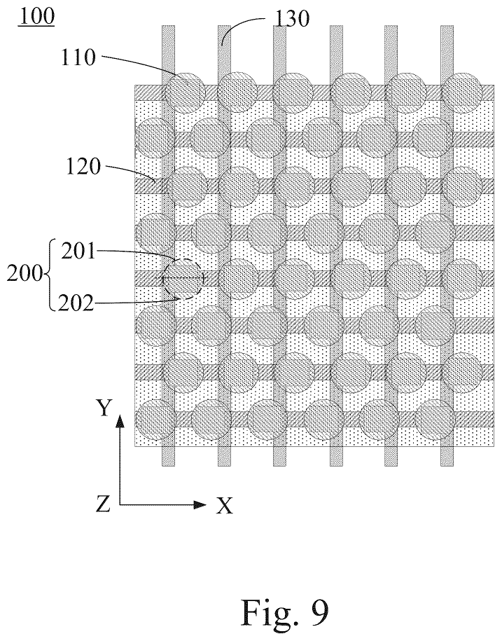

FIG. 9 is a schematic diagram of a film layer of a semiconductor structure 100 in the context of yet another CAA transistor, provided by some implementations of the present disclosure.

As shown in FIGS. 3 and 9, in some implementations, the capacitor unit 200 includes a first side 201 and a second side 202 in a direction parallel to the plane where the first direction X and the second direction Y are located, wherein the first side 201 and the second side 202 are on both sides of the channel structure 110 in the direction, respectively. When the transistor structure is a CAA transistor, the first side 201 and the second side 202 of the capacitor unit 200 are on both sides of the connection 113 of the channel structure 110 in the direction, respectively.

In an example, in this implementation, when the channel structure 110 and the capacitor unit 200 are projected along the third direction Z, the projection of the channel structure 110 may be inside the projection of the capacitor unit 200. That is to say, in the third direction Z, the projection boundary of the channel structure 110 is inside the projection boundary of the capacitor unit 200.

In the manufacturing process of semiconductor structure 100, in this way, the difficulty of alignment between the channel structure 110 and the capacitor unit 200 may be reduced, thereby reducing the difficulty of the manufacturing process of the semiconductor structure 100.

Moreover, by improving the alignment accuracy between the channel structure 110 and the capacitor unit 200, the electrical connection effect between the channel structure 110 and the capacitor unit 200 may also be improved, thereby enhancing the reliability and stability of the semiconductor structure 100.

Please continue to refer to FIGS. 7 and 8. In some implementations, the capacitor unit 200 includes a first electrode 210, a second electrode 220, and a first dielectric layer 230. The first electrode 210 extends along the third direction Z, and when the transistor structure is a GAA transistor, the first electrode 210 is connected to the end of the channel structure 110 away from the bit line 130. When the transistor structure is a CAA transistor, the first electrode 210 is connected to the end of the first sub-channel 111 away from the bit line 130 and to the end of the second sub-channel 112 away from the bit line 130. The second electrode 220 surrounds at least a part of the first electrode 210, and the first dielectric layer 230 is between the first electrode 210 and the second electrode 220.

In an example, the first electrode 210 may be columnar, such as cylindrical, etc. The first electrode 210 may extend along the third direction Z. The end of the first electrode 210 close to the channel structure 110 may be electrically connected to the channel structure 110.

In a feasible implementation, the columnar structure of the first electrode 210 may be manufactured from a conductive material, so that the number of times of depositing the conductive material required in the manufacturing process may be reduced, thereby simplifying the manufacturing process flow and reducing the manufacturing cost. In an example, the conductive material may include titanium nitride or other suitable materials.

Moreover, in this way, when the distance between two adjacent capacitor units 200 deviates from the set distance during the process of manufacturing a plurality of capacitor units 200, the distance between two adjacent capacitor units 200 may be adjusted by adjusting the circumference of the columnar structure of the first electrode 210, thereby improving the error tolerance of a plurality of capacitor units 200 during the manufacturing process and thus reducing the difficulty of manufacturing capacitor units 200.

In an example, when the distance between two adjacent capacitor units 200 is small, due to the columnar structure of the first electrode 110, the distance between two adjacent capacitor units 200 may be adjusted by adjusting the thickness of the first electrode 110. That is to say, a portion of the first electrode 110 may be removed to reduce the width of the first electrode 110 in the first direction X, thereby increasing the distance between two adjacent capacitor units 200, so as to adjust the distance between two adjacent capacitor units 200.

In another feasible implementation, the columnar structure of the first electrode 210 may be manufactured from two materials. In an example, the first electrode 210 includes a first electrode body layer and a first electrode filling structure. Herein, the first electrode filling structure is a columnar structure, and the inner first electrode body layer surrounds one first electrode filling structure for one circle. In this way, the first electrode filling structure may be utilized to support the first electrode body layer, so that the manufactured first electrode 210 may provide support force for the capacitor unit 200, thereby improving the reliability and stability of the capacitor unit 200.

In some other implementations, the first electrode 210 may also exist in other suitable structures, which is not limited by implementations of the present disclosure.

Herein, in the actual manufacturing process, since the manufacturing process of the first electrode 210 mostly adopts any suitable etching process such as dry etching or wet etching, as the etching depth in the third direction Z increases, the width of the manufactured hole will gradually decrease with the increase of etching depth, resulting in a gradual decrease in the size of the first electrode 210 manufactured in the hole in the first direction X. That is to say, when the transistor structure is a GAA transistor, in the third direction Z, the size H3 of the end of the first electrode 210 close to the channel structure 110 is greater than the size H4 of the end of the first electrode 210 away from the channel structure 110. When the transistor structure is a CAA transistor, in the third direction Z, the size of the end of the first electrode 210 close to the first sub-channel 111 is larger than the size of the end of the first electrode 210 away from the first sub-channel 111.

Please continue to refer to FIGS. 7 and 8. When the columnar structure of the first electrode 210 is manufactured from a conductive material, a second electrode filling structure 270 may also be disposed between the second electrodes 220 of the plurality of capacitor units 200.

In this implementation, by disposing the second electrode filling structure 270, support force may be provided for the entire columnar structure of the first electrode 210, thereby increasing the stability of the first electrode 210 in the third direction Z, preventing the problem of bending of the first electrode 210, and improving the stability of each capacitor unit 200 within the entire capacitor unit layer.

In some examples, the second electrode filling structure 270 may be columnar, such as cylindrical, etc., and the material of the second electrode filling structure 270 may include a germanium silicon material. Due to the conductivity of germanium silicon material, connection of the second electrode 220 to an external device such as a power supply may be achieved. Moreover, germanium silicon material may reduce the structural stress on the internal first electrode 210, which is also beneficial for improving the structural stability of the first electrode 210, as well as the stability and reliability of the entire capacitor unit 200.

Moreover, as a feasible implementation, a plurality of capacitor units 200 may be disposed in an array. Based on this, a plurality of second electrode filling structures 270 may also be disposed in an array to provide uniform support force using the array of second electrode filling structures 270, thereby improving the stability of the entire capacitor unit layer.

Moreover, the uniformly distributed second electrode filling structure 270 may reduce the waste of internal space of a capacitor unit layer, thereby reasonably occupying the internal space of the capacitor unit layer, optimizing the support of a plurality of first electrodes 210 by a single second electrode filling structure 270, in turn improving the utilization rate of the second electrode filling structure 270 and avoiding the occurrence of bending of the first electrode 210.

Please continue to refer to FIGS. 7 and 8. In some implementations, a capacitor unit layer may also include a plurality of electrode filling layers 280 and a plurality of support layers 290, wherein the plurality of electrode filling layers 280 and the plurality of support layers 290 are stacked alternately, and the first electrode 210 and the second electrode filling structure 270 pass through each electrode filling layer 280 and each support layer 290.

In this implementation, by stacking the electrode filling layer 280 and the support layer 290 alternately along the third direction Z, support force may be provided for the first electrode 210 and the second electrode filling structure 270, avoiding bending of the columnar structures of the first electrode 210 and the second electrode filling structure 270.

In some examples, the material of the electrode filling layer 280 may be the same as or different from the material of the second electrode filling structure 270. When the material of the electrode filling layer 280 is the same as that of the second electrode filling structure 270, the second electrode filling structure 270 and the electrode filling layer 280 may be manufactured in the same manufacturing process, thereby simplifying the manufacturing process of the capacitor unit layer and improving the manufacturing efficiency of the capacitor unit layer and the semiconductor structure 100.

Herein, when the material of the electrode filling layer 280 is the same as that of the second electrode filling structure 270, a plurality of electrode filling layers 280 and a plurality of second electrode filling structures 270 are connected in an integral structure. That is to say, structurally, there is no clear boundary between the plurality of electrode filling layers 280 and the plurality of second electrode filling structures 270.

Moreover, since the first electrode 210 and the second electrode filling structure 270 pass through each electrode filling layer 280 and each support layer 290, each electrode filling layer 280 and each support layer 290 may be in a mesh structure. In this way, such a support structure mesh-shaped may be utilized to provide more uniform support force for the first electrode 210 and the second electrode filling structure 270, thereby making the first electrode 210 and the second electrode filling structure 270 more stable, and thus making the capacitor unit 200 more stable and reliable.

Please continue to refer to FIGS. 7 and 8. In some implementations, a plurality of second electrode filling structures 270 may be in an integral structure, so that the second electrodes 220 of a plurality of capacitor units 200 may be collectively led out via the second electrode filling structures 270 in the subsequent situation of leading out the capacitor unit 200 to power supply, thereby reducing the number of lead-out structures required for the semiconductor structure 100, in turn simplifying the semiconductor structure 100, and reducing the difficulty of leading out of the semiconductor structure 100, improving the reliability and stability of the semiconductor structure 100.

In an example, in a feasible implementation, an interconnect layer 260 may be disposed to lead out the integral structure constituted by a plurality of second electrode filling structures 270, thereby leading out the second electrodes 220 of a plurality of capacitor units 200.

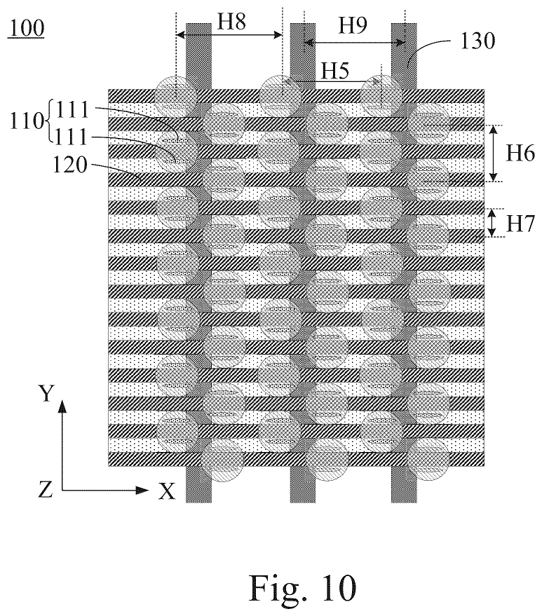

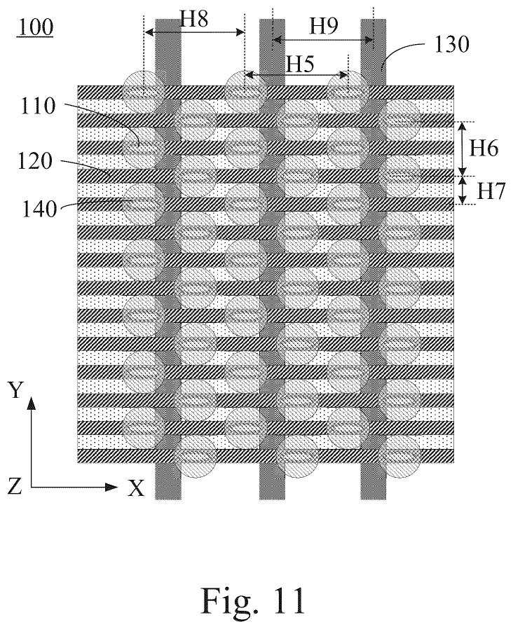

FIG. 10 is a schematic diagram of a film layer of a semiconductor structure 100 in the context of another GAA transistor, provided by some implementations of the present disclosure. FIG. 11 is a schematic diagram of a film layer of a semiconductor structure 100 in the context of another CAA transistor, provided by some implementations of the present disclosure.

In some implementations, the first direction X may be perpendicular to the second direction Y. In this implementation, when two adjacent columns of channel structures 110 are in a staggered arrangement, multiple different film layer morphologies may be obtained by adjusting the distance H5 between two adjacent channel structures 110 in a row and the distance H6 between two adjacent channel structures 110 in a column.

In an example, when the distance H5 between two adjacent channel structures 110 in a row is greater than the distance H6 between two adjacent channel structures 110 in a column, the film layer morphology shown in FIGS. 10 and 11 may be obtained. Alternatively, when the distance H5 between two adjacent channel structures 110 in a row is less than the distance H6 between two adjacent channel structures 110 in a column, the film layer morphology shown in FIGS. 3 and 5 may be obtained.

In any of the film layer morphologies described above, the ratio of the distance H7 between two adjacent word lines 120 to the distance H8 between two adjacent capacitor units 200 is greater than or equal to 0.25 and less than or equal to 0.9. The ratio of the distance H9 between two adjacent bit lines 130 to the distance H8 between two adjacent capacitor units 200 is greater than or equal to 0.5 and less than or equal to 1.9.

Herein, in some examples, H7/H8 is greater than or equal to 0.25, and therefore, H7≥0.25×H8, which may avoid H7 being too small, for example, H7<0.25×H8. In an example, if H7 is too small, such as H7<0.2×H8, the distance H7 between two adjacent word lines 120 is too small, so that the channel structure 110 manufactured on these two word lines 120 may easily miscontact other capacitor units 200 during the process of contacting the channel structure 110 with the corresponding capacitor unit 200, resulting in a decrease in the stability and reliability of the semiconductor structure 100. Therefore, if H7/H8 is greater than or equal to 0.25, the distance H7 between two adjacent word lines 120 may be increased by increasing the value of H7, thereby avoiding the channel structure 110 on two adjacent word lines 120 miscontacting a plurality of capacitor units 200 during the process of joining the channel structure 110 with the capacitor unit 200, and thus improving the stability and reliability of the semiconductor structure 100. Moreover, by increasing the distance H7 between two adjacent word lines 120, the difficulty of manufacturing word lines 120 and the channel structure 110 on word lines 120 may also be reduced. Therefore, H7≥0.25×H8.

And, H7/H8 is less than or equal to 0.9, and therefore, H7≤0.9×H8, which may avoid the distance H7 between two adjacent word lines 120 being too large, for example, H7>0.9×H8. In an example, if H7 is too large, such as H7>H8, the distance H7 between two adjacent word lines 120 is too large, so that the width of the word line 120 in the second direction Y is too small, and thus the difficulty of manufacturing the channel structure 110 on the word lines 120 is increased. Alternatively, since the width of the word line 120 in the second direction Y is too small, the area of the manufactured channel structure 110 is too small, thereby reducing the interface area between the channel structure 110 and the capacitor unit 200, increasing the contact resistance between the channel structure 110 and the capacitor unit 200, and increasing the device loss of the semiconductor structure 100. Therefore, H7≤0.9×H8.

In an example, the ratio of the distance H7 between two adjacent word lines 120 to the distance H8 between two adjacent capacitor units 200 may include any suitable ratio of such as 0.25, 0.3, 0.4, 0.5, 0.6, 0.7, 0.8, \sqrt{3}/2, 0.9, etc., which is not limited by implementations of the present disclosure. In some other examples, H9/H8 is greater than or equal to 0.5, and therefore H9≥0.5×H8, which may avoid H9 being too small, for example, H9>0.5×H8. In an example, if H9 is too small, such as H9<0.3×H8, the distance between two adjacent bit lines 130 is too small, which may cause these two bit lines 130 to easily contact the channel structures 110 corresponding to other bit lines 130 during the connection process with the channel structure 110, thereby reducing the stability and reliability of the semiconductor structure 100. Therefore, if H9/H8 is greater than or equal to 0.5, the distance H9 between two adjacent bit lines 130 may be increased by increasing the value of H9, thereby avoiding the problem of two adjacent bit lines 130 contacting the channel structure 110 corresponding to other bit lines 130 during the connection process with the channel structure 110, and thus reducing the difficulty of the manufacturing process of bit lines 130 and improving the stability and reliability of the semiconductor structure 100. Moreover, by increasing the distance H9 between two adjacent bit lines 130, the coupling effect between two adjacent bit lines 130 may be reduced, thereby improving the performance of the semiconductor structure 100. Therefore, H9≥0.5×H8.

And, H9/H8 is less than or equal to 1.9, and therefore, H9≤1.9×H8, which may avoid the distance H9 between two adjacent bit lines 130 being too large, for example, H9>1.9×H8. In an example, if H9 is too large, such as H9>2×H8, the distance H9 between two adjacent bit lines 130 is too large, resulting in the width of bit line 130 in the first direction X being too small, making it difficult for a single bit line 130 to contact two adjacent columns of channel structures 110, and thereby affecting the electrical connection effect between the bit line 130 and the channel structure 110. Alternatively, since the distance H9 between two adjacent bit lines 130 is to large, the density between a plurality of channel structures 110 is decreased, which is not conducive to further miniaturization of the semiconductor structure 100 in size. Therefore, H9≤1.9×H8. In an example, the ratio of the distance H9 between two adjacent bit lines 130 to the distance H8 between two adjacent capacitor units 200 may include any suitable ratio of such as 0.5, 0.6, 0.8, \sqrt{3}/2, 0.9, 1, 1.5, \sqrt{3}, 1.9, etc., which is not limited by implementations of the present disclosure. Herein, when the first direction X may be perpendicular to the second direction Y, when a plurality of channel structures 110 are arranged in the film layer layout shown in FIGS. 10 and 11, the ratio of the distance H7 between two adjacent word lines 120 to the distance H8 between two adjacent capacitor units 200 is \sqrt{3}/2, and the ratio of the distance H9 between two adjacent bit lines 130 to the distance H8 between two adjacent capacitor units 200 is 1. When a plurality of channel structures 110 are arranged in the film layer layout shown in FIGS. 3 and 5, the ratio of the distance H7 between two adjacent word lines 120 to the distance H8 between two adjacent capacitor units 200 is 1/2, and the ratio of the distance H9 between two adjacent bit lines 130 to the distance H8 between two adjacent capacitor units 200 is \sqrt{3}.

In this implementation, by making the first direction X perpendicular to the second direction Y, the manufactured word line 120 may be orthogonal to the bit line 130, thereby reducing the layout difficulty of the film layer in the manufacturing process of the semiconductor structure 100, and thus reducing the manufacturing process difficulty of the semiconductor structure 100.

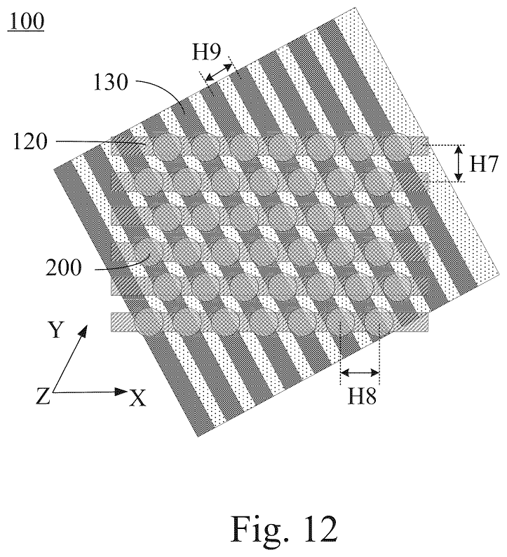

FIG. 12 is a schematic diagram of a film layer of yet another semiconductor structure provided by some implementations of the present disclosure.

In some other implementations, the first direction X may not be perpendicular to the second direction Y, that is, the angle between the first direction X and the second direction Y may also be any other suitable angle, which is not limited by implementations of the present disclosure.

In an example, as shown in FIG. 12, the angle between the first direction X and the second direction Y may be 60 degrees. In this scenario, the ratio of the distance H7 between two adjacent word lines 120 to the distance H8 between two adjacent capacitor units 200 is \sqrt{3}/2, and the ratio of the distance H9 between two adjacent bit lines 130 to the distance H8 between two adjacent capacitor units 200 is \sqrt{3}/2.

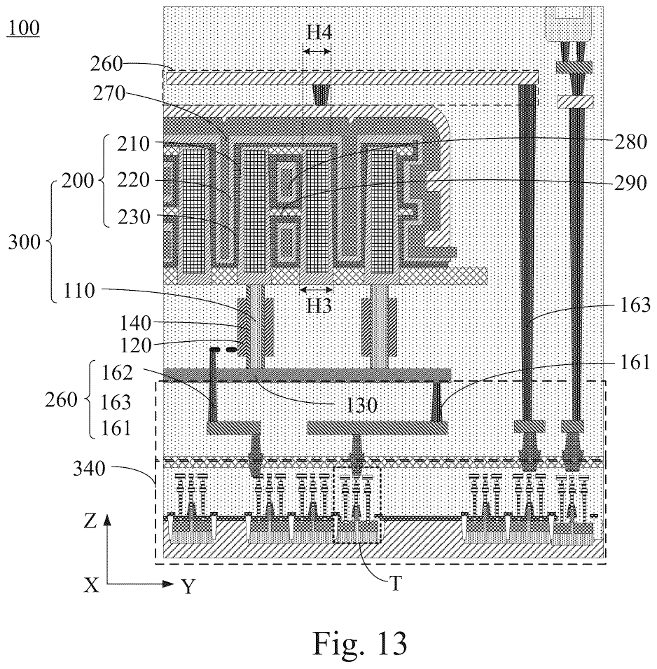

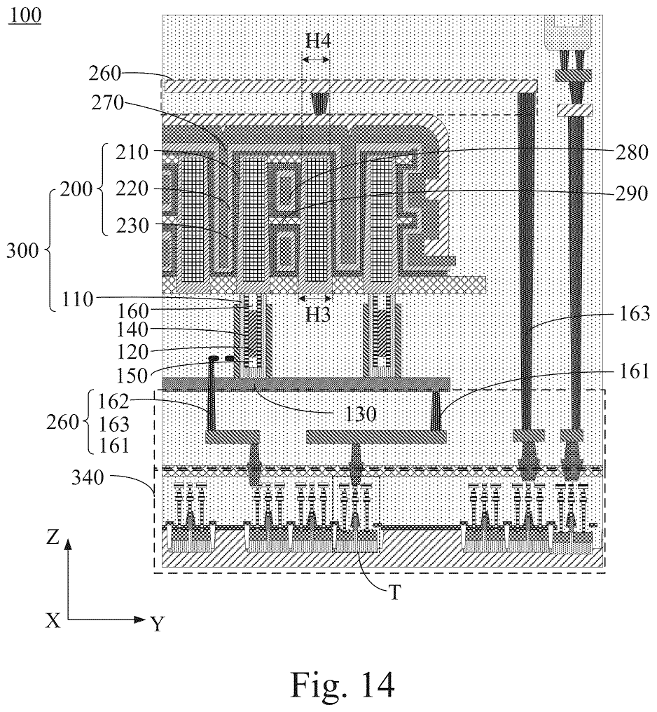

FIG. 13 is a structural schematic diagram of a semiconductor structure 100 in the context of yet another GAA transistor, provided by some implementations of the present disclosure. FIG. 14 is a structural schematic diagram of a semiconductor structure 100 in the context of yet another CAA transistor, provided by some implementations of the present disclosure.

As shown in FIGS. 13 and 14, in some implementations, the semiconductor structure 100 further includes an interconnect layer 260 located on a side of the memory array 300 including the channel structure 110 and the capacitor unit 200 in the third direction Z. In an example, the interconnect layer 260 may be stacked on a side of the bit line 130 away from the capacitor unit 200. Alternatively, the interconnect layer 260 may also be stacked on a side of the capacitor unit 200 away from the bit line 130.

The interconnect layer 260 includes a first connection structure 161, a second connection structure 162, and a third connection structure 163. Herein, in some implementations, the first connection structure 161 is connected to the bit line 130, a part of the second connection structure 162 extends into the memory array 300 and is connected to the word line 120, and a part of the third connection structure 163 extends into the memory array 300 and is connected to the capacitor unit 200.

In some other implementations, the first connection structure may also be connected to a capacitor unit, a part of the second connection structure may extend into a memory array and be connected to a bit line, and a part of the third connection structure may extend into a memory array and be connected to a word line.

In this implementation, by disposing the interconnect layer 260, the first connection structure 161, the second connection structure 162, and the third connection structure 163 within the interconnect layer 260 may be configured to lead out the memory array 300, thereby achieving signal transmissions between the word lines 120, bit lines 130, and capacitor units 200 within the memory array 300 and other device structures, and thus enabling control of the DRAM cells by other device structures. Herein, the connection may include an electrical connection or a physical connection.

In some examples, the first connection structure 161, the second connection structure 162, and the third connection structure 163 may all include through silicon contacts (TSC), through silicon contact parts, and the like. Moreover, in an example, the shape of the first connection structure 161, the shape of the second connection structure 162, and the shape of the third connection structure 163 may be the same or different.

Moreover, when the number of first connection structures 161, the number of second connection structures 162, and the number of third connection structures 163 are all multiple, the shapes of a plurality of first connection structures 161 may be the same or different. The shapes of a plurality of second connection structures 162 may be the same or different. Similarly, the shapes of a plurality of third connection structures 163 may be the same or different, and implementations of the present disclosure are not limited to them.

Moreover, as a feasible implementation, the interconnect layer 260 mentioned above may also include at least one layer of circuit structures, so that a plurality of first connection structures 161, a plurality of second connection structures 162, and a plurality of third connection structures 163 may be led out through the internal circuit structures (such as interconnects). Herein, a circuit layer may also include inter-layer dielectrics to achieve isolation between circuit structures.

In an example, inter-layer dielectrics may be made of dielectric materials, including but not limited to silicon oxide, silicon nitride, silicon oxynitride, low dielectric constant dielectrics, or any combination thereof, which is not limited by implementations of the present disclosure.

The first connection structure 161, the second connection structure 162, and the third connection structure 163 may all include a conductive material, for example, including but not limited to W, Co, Cu, Al, doped silicon, silicide, or any combination thereof. The conductive materials used for the first connection structure 161, the second connection structure 162, and the third connection structure 163 may be the same or different, which is not limited by implementations of the present disclosure.

Please continue to refer to FIGS. 13 and 14. In some implementations, the semiconductor structure 100 further includes a peripheral device 340. The peripheral device 340 are stacked on a side of the interconnect layer 260 away from the memory array 300, and are coupled to the memory array 300 through the interconnect layer 260.

In this implementation, the peripheral device 340 may include a plurality of control transistors T. The interconnect layer 260 may realize the coupling between the peripheral device 340 and the DRAM cell, and realize the coupling between a plurality of control transistors T in the peripheral device 340 and the DRAM cell, thereby realizing the transmission of electrical signals between the control transistors T and the transistor structures of the DRAM cell, and thus controlling the DRAM cell by using the control transistor T to achieve the write, read, and erase of data.

Based on the semiconductor structures 100 provided in some implementations mentioned above, an implementation of the present disclosure further provides a manufacturing method of a semiconductor structure 100, via which the semiconductor structures 100 mentioned above may be manufactured.

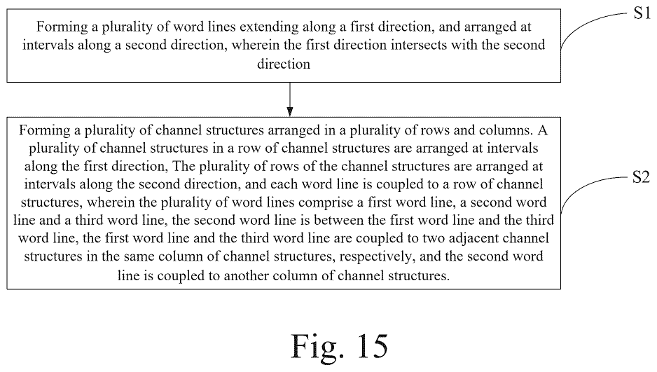

FIG. 15 is a flowchart of a manufacturing method of a semiconductor structure in the context of a GAA transistor, provided in some implementations of the present disclosure.

As shown in FIG. 15, in some implementations, the manufacturing method of the semiconductor structure 100 includes the following operations S1 to S2.

S1: Forming a plurality of word lines extending along a first direction, and arranged at intervals along a second direction, wherein the first direction intersects with the second direction.

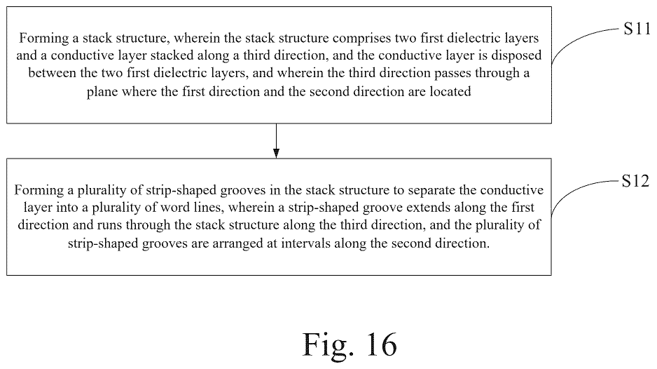

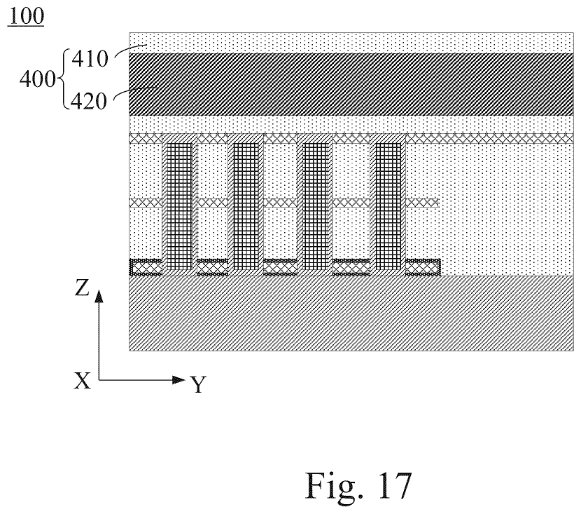

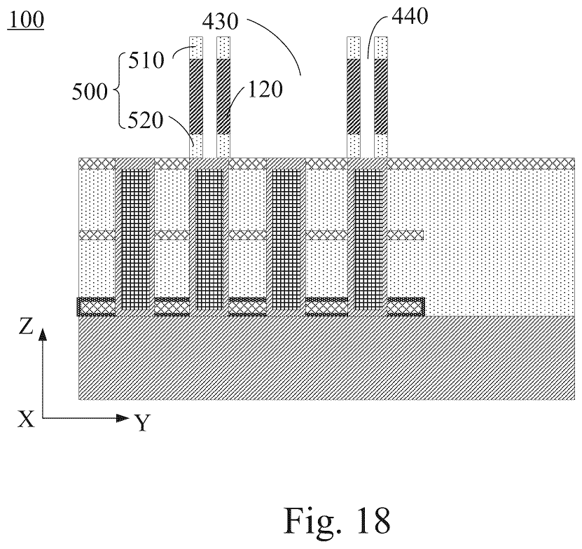

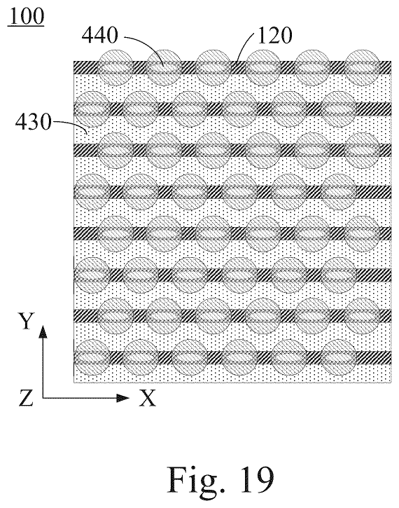

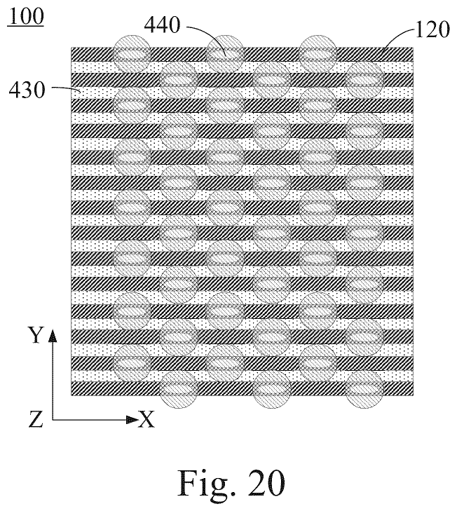

FIG. 16 is a flowchart of a manufacturing method of a word line 120 in the context of a GAA transistor, provided by some implementations of the present disclosure. FIG. 17 is a structural schematic diagram of a semiconductor structure 100 corresponding to the manufacturing method in FIG. 16. FIG. 18 is a structural schematic diagram of another semiconductor structure 100 corresponding to the manufacturing method in FIG. 16. FIG. 19 is a schematic diagram of a film layer corresponding to the semiconductor structure 100 in FIG. 18. FIG. 20 is a schematic diagram of another film layer corresponding to the semiconductor structure 100 in FIG. 18.

As shown in FIG. 16, the above operation S1 may also include the following operations S11-S12.

S11: Forming a stack structure, wherein the stack structure comprises two first dielectric layers and a conductive layer stacked along a third direction, and the conductive layer is disposed between the two first dielectric layers, and wherein the third direction passes through a plane where the first direction and the second direction are located.

In operation S11, chemical vapor deposition (CVD), physical vapor deposition (PVD), atomic layer deposition (ALD), or any combination of these thin film deposition processes may be used to form two first dielectric layers 410 and a conductive layer 420, thereby forming the stack structure 400 as shown in FIG. 17.

Herein, the material of the first dielectric layer 410 may include an insulating material, which may include one or more of an oxide material (such as silicon oxide), nitride material (such as silicon nitride), and oxynitride material (such as silicon oxynitride), which is not limited by implementations of the present disclosure. The material of the conductive layer 420 may include a conductive material, such as wolfram (W), cobalt (Co), copper (Cu), aluminum (Al), doped silicon, silicide, or any combination thereof, which is not limited by implementations of the present disclosure. In an example, in this implementation, the insulating material that constitutes the first dielectric layer 410 may include silicon oxide, and the conductive material that constitutes the conductive layer 420 may include wolfram.

As a feasible implementation, in the manufacturing process of the stack structure 400, a chemical vapor deposition, physical vapor deposition, atomic layer deposition, or any combination of these thin film deposition processes may be used to form a first dielectric layer 410. After forming a first dielectric layer 410, a conductive layer 420 is formed on the first dielectric layer 410, and then another first dielectric layer 410 is formed on the conductive layer 420.

Herein, similarly, the conductive layer 420 and another subsequently manufactured first dielectric layer 410 may also be formed using a chemical vapor deposition, physical vapor deposition, atomic layer deposition, or any combination of these thin film deposition processes, which is not limited by implementations of the present disclosure.

S12: Forming a plurality of strip-shaped grooves in the stack structure to separate the conductive layer into a plurality of word lines, wherein a strip-shaped groove extends along the first direction and runs through the stack structure along the third direction, and the plurality of strip-shaped grooves are arranged at intervals along the second direction.

In operation S12, a photoresist layer may be formed on the surface of a side of the first dielectric layer in a suitable manner such as static spin coating or dynamic spray coating, etc., and the photoresist layer may be patterned to obtain a first mask layer with a plurality of first openings.

As a feasible implementation, the photoresist may be coated in any suitable manner such as static spin coating or dynamic spray coating, etc.

As shown in FIGS. 17 and 18, as an example, in this implementation, by using any suitable process such as self-aligned double patterning (SADP), etc., the stack structure 400 may be etched based on the first mask layer, to remove a part of the stack structure 400 and form a plurality of strip-shaped grooves 430 that run through the stack structure along the third direction Z. Herein, the plurality of strip-shaped grooves 430 may be arranged at intervals along the second direction Y, so as to use the plurality of strip-shaped grooves 430 to separate the conductive layer 420 into the plurality of word lines 120 as shown in FIGS. 19 and 20.

Herein, in an example, since the stack structure 400 is formed by stacking two first dielectric layers 410 and a conductive layer 420, when a plurality of strip grooves 430 separate the conductive layer 420 into a plurality of word lines 120, the first dielectric layer 410 on both sides of the strip grooves 430 in the third direction Z will also be separated into a plurality of insulations 500 by a plurality of strip grooves 430.

Herein, an insulation 500 may include a first insulation 510 and a second insulation 520. In an example, the first insulation 510 is disposed on a side of the word line 120 along the third direction Z, and the second insulation 520 is disposed on the other side of the word line 120 along the third direction Z.

In this operation S12, by manufacturing a plurality of word lines 120, a column of channel structures connected to a single word line 120 may be selected by using the word lines 120 when the manufacturing process of the plurality of channel structures 110 (see FIG. 13) is completed subsequently, so that in combination with the subsequently manufactured bit lines 130 (see FIG. 13), the on and off control of a single channel structure 110 may be enabled, and control of the charging and discharging of the capacitor unit 200 (see FIG. 13) may be enabled by using the channel structure 110, so as to realize the read, write, or erase operations of data by the DRAM cell.

Moreover, when the subsequent manufacturing of the channel structure 110 is completed, the both ends of the channel structure 110 in the third direction Z need to be in contact with the capacitor unit 200 or the bit line 130. Therefore, in operation S12, by forming the first insulation 510 and the second insulation 520, the isolation between the word line 120 and the capacitor unit 200 or the bit line 130 may be achieved using the first insulation 510 and the second insulation 520, thereby avoiding contact between the word line 120 and the capacitor unit 200 or the bit line 130 and improving the reliability of the semiconductor structure 100.

Moreover, in some examples, the manufacturing process of the word line 120 may be carried out before manufacturing the channel structure 110, so that the limitation on the material of the channel structure 110 may be reduced. For example, the material of the channel structure 110 may include a low-temperature material such as IGZO.

In this way, a heat treatment process may be performed on the metal material of the word line 120 to remove the redundant impurities in the material of the word line 120, thereby improving the material purity of the word line 120, in turn reducing the resistance of the manufactured word line 120, and reducing the device loss of the manufactured semiconductor structure 100.

In some other examples, the manufacturing process of the word line 120 may also be performed after the manufacturing of the channel structure 110, which is not limited by implementations of the present disclosure.

S2: Forming a plurality of channel structures arranged in a plurality of rows and columns. A plurality of channel structures in a row of channel structures are arranged at intervals along the first direction, the plurality of rows of channel structures are arranged at intervals along the second direction, and each word line is coupled to a row of channel structures, wherein the plurality of word lines comprise a first word line, a second word line and a third word line, the second word line is between the first word line and the third word line, the first word line and the third word line are coupled to two adjacent channel structures in the same column of channel structures, respectively, and the second word line is coupled to another column of channel structures.

Please continue to refer to FIG. 4. In practical applications, the position of the manufactured word line 120 corresponding to a single channel structure 110 in a row of channel structures 110 may serve as a gate corresponding to the single channel structure 110 in the row of channel structures 110. Based on this, when a portion of the word line 120 corresponding to a single channel structure 110 may serve as a gate, the portion and the channel structure 110 may constitute a transistor structure.

Please continue to refer to FIG. 3, where the manufactured plurality of channel structures 110 is in the layout. A plurality of word lines 120 may include a first word line 121, a second word line 122, and a third word line 123. Herein, the second word line 122 is between the first word line 121 and the third word line 123. The first word line 121 and the third word line 123 are coupled to two adjacent channel structures 110 in the same column, respectively, and the second word line 122 is coupled to another column of channel structures 110.

In this way, a staggered arrangement between two adjacent columns of channel structures 110 may be achieved when the manufactured plurality of channel structures 110 are arranged in a plurality of columns.

Moreover, in this implementation, by arranging the manufactured two adjacent columns of channel structures 110 in a staggered manner, a hexagonal arrangement among a plurality of channel structures 110 is achieved when the channel structures 110 are in a plurality of columns. In this way, the device density among a plurality of channel structures 110 is increased and the layout area of the semiconductor structure 100 occupied by a plurality of channel structures 110 is reduced under the condition that the number of channel structures 110 is not changed.

Moreover, in some examples, due to the hexagonal arrangement of a plurality of channel structures 110 in implementations of the present disclosure, if the layout of a plurality of capacitor units 200 (see FIG. 7) in the capacitor structure layer connected to a plurality of channel structures 110 also adopts a hexagonal arrangement, a plurality of channel structures 110 may be directly connected to a plurality of capacitor units when manufacturing a DRAM cell array. That is to say, each channel structure 110 may be directly connected to a capacitor unit without the need for additional transition structures (such as connection contacts, etc.) between the two.

In this way, the semiconductor structure 100 may be simplified, the height of the semiconductor structure 100 in the third direction Z may be reduced, thereby increasing the device density of the semiconductor structure 100 and facilitating further miniaturization of the semiconductor structure 100 in size.

In other examples, the layout of a plurality of capacitor units 200 in the capacitor structure layer connected to a plurality of channel structures 110 may also adopt other forms, and the connection between a plurality of channel structures 110 and a plurality of capacitor units 200 may also be achieved through an adapter structure, which is not limited by implementations of the present disclosure.

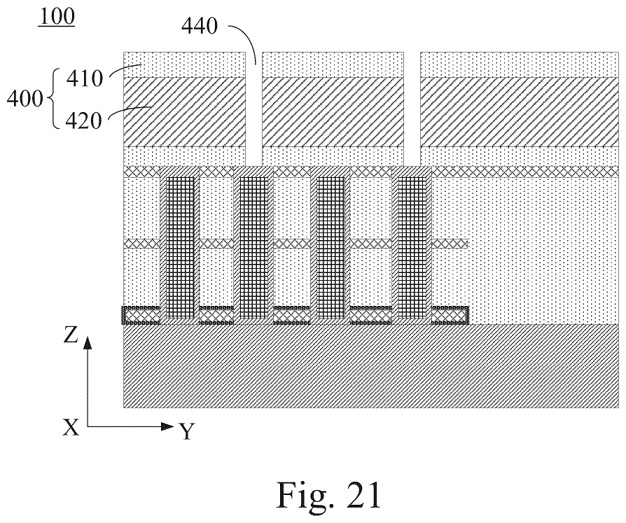

FIG. 21 is a structural schematic diagram of a semiconductor structure 100 corresponding to a manufacturing method, provided in implementations of the present disclosure.

In some implementations, before completing the manufacturing of the plurality of channel structures 110 in operation S2 described above, the manufacturing method of semiconductor structure 100 may further include the following operation S21.

S21: Forming a plurality of first through-holes 440 in the stack structure 400, wherein a first through-hole 440 runs through the stack structure 400 along the third direction Z, and the plurality of first through-holes 440 are arranged in a plurality of rows and columns, a plurality of first through-holes 440 in a row of first through-holes are arranged at intervals along the first direction X, and the plurality of rows of first through-holes 440 are arranged at intervals along the second direction Y, and wherein the strip-shaped groove 430 is formed between two adjacent rows of first through-holes 440.

In an example, in operation S21, suitable processes such as static spin coating or dynamic spray coating, etc. may be used to form a photoresist layer on the surface of a side of the first dielectric layer 410, and the photoresist layer may be patterned to obtain a second mask layer with a plurality of second openings.

As shown in FIG. 21, any suitable etching process such as dry etching or wet etching, etc. may be used to etch the stack structure 400 exposed by a plurality of second openings through a plurality of second openings, so as to remove parts of the stack structure 400 and form a plurality of first through-holes 440 arranged in an array.

Herein, the plurality of strip-shaped grooves 430 (see FIG. 18) manufactured in the afore-mentioned operation S12 described above may be arranged at intervals among a plurality of columns of first through-holes 440 along the second direction Y, so that each column of first through-holes 440 may be formed on a column of word lines 120 when the conductive layer 420 is separated into a plurality of word lines 120 by a plurality of strip-shaped grooves 430 subsequently.

In practical applications, the process of manufacturing the first through-hole 440 may be performed before the process of manufacturing the strip-shaped groove 430. Alternatively, the process of manufacturing the first through-hole 440 may also be performed after the process of manufacturing the strip-shaped groove 430. Implementations of the present disclosure are not limited to this, and the specific sequence of the manufacturing process may be adjusted according to actual needs.

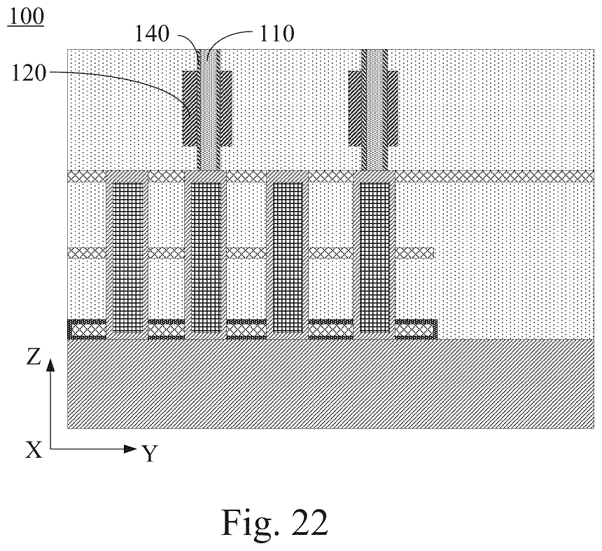

FIG. 22 is a structural schematic diagram of another semiconductor structure 100 corresponding to a manufacturing method, provided in implementations of the present disclosure.

In some implementations, the manufacturing method of the plurality of channel structures 110 in operation S2 described above may also include the following operation S22.

S22: Forming a conductive material within the first through-holes to form the channel structures.

As shown in FIG. 22, in this operation S22, a chemical vapor deposition, physical vapor deposition, atomic layer deposition, or any combination of these thin film deposition processes may be used to deposit a semiconductor material in the first through-hole, thereby forming the channel structure 110.

Herein, in an example, a semiconductor material may include IGZO, silicon, doped silicon, germanium, or any other suitable material, which is not limited by implementations of the present disclosure. For example, in this implementation, the material of the channel structure 110 may include an oxide semiconductor material, such as IGZO.

In this way, the manufactured channel structure 110 may have a smaller leakage current, thereby prolonging the data storage time of DRAM cells and reducing the device loss of the semiconductor structure 100. Moreover, due to the higher carrier mobility of IGZO, under the same requirements, the size of the manufactured channel structure 110 may be reduced by using IGZO, which is beneficial for the miniaturization of the semiconductor structure 100.

In some implementations, before the manufacturing of the channel structure 110 in operation S22 described above, the manufacturing method of the semiconductor structure may further include the following operation S220.

S220: Forming a gate dielectric layer 140 on a sidewall of a first through-hole 440.

Please continue to refer to FIG. 22. In this operation S220, a chemical vapor deposition, physical vapor deposition, atomic layer deposition, or any combination of these thin film deposition processes may be used to deposit an insulating material in the first through-hole to form the gate dielectric layer 140.

Herein, in an example, an insulating material may include one or more of an oxide material (such as silicon oxide), nitride material (such as silicon nitride), and oxynitride material (such as silicon oxynitride). Alternatively, the material of the gate dielectric layer 140 may also include any suitable high dielectric constant (high-K) material such as aluminum oxide, chromium oxide, zirconium oxide, etc., which is not limited by implementations of the present disclosure.

In this implementation, by disposing a gate dielectric layer 140 between the channel structure 110 and the word line 120, isolation between the channel structure 110 and the word line 120 may be achieved, thereby avoiding direct current conduction between the channel structure 110 and the word line 120.

As a feasible implementation, the material of the gate dielectric layer 140 in this implementation may include aluminum oxide when the material of the channel structure 110 includes IGZO. In this way, the word line 120 may be coordinated to achieve more precise control of the on and off states of the transistor structure, thereby effectively reducing the leakage current of the transistor structure and improving the device performance and reliability of the semiconductor structure 100.

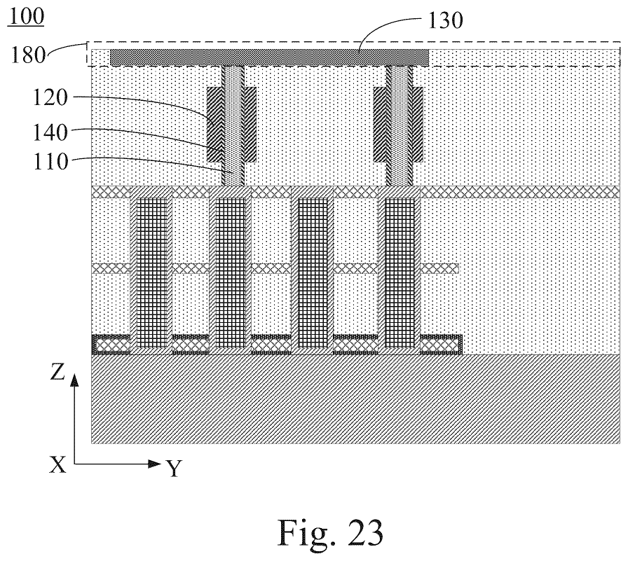

FIG. 23 is a structural schematic diagram of yet another semiconductor structure 100 corresponding to a manufacturing method, provided in implementations of the present disclosure.

As shown in FIG. 23, after completing the manufacturing of the channel structure 110 in the afore-mentioned operation S22, the manufacturing method of the semiconductor structure 100 may further include the following operation S3.

S3: Forming a bit line 130, wherein the bit line 130 is formed at the end of a channel structure 110 along a third direction Z, extends along the second direction Y, and is connected with the ends of two adjacent columns of channel structures 110, and wherein the third direction Z passes through a plane where the first direction X and the second direction Y are located.

Please continue to refer to FIG. 23. In an example, in this operation S3, a chemical vapor deposition, physical vapor deposition, atomic layer deposition, or any combination of these thin film deposition processes may be used to deposit an insulating material on a side of the channel structure 110 in the third direction Z to form an insulating layer 180.

In an example, suitable processes such as static spin coating or dynamic spray coating, etc. may be used to form a photoresist layer on a side of the insulating layer 180, and the photoresist layer may be patterned to obtain a fourth mask layer with a plurality of fourth openings.

Any suitable etching process such as dry etching or wet etching, etc. may be used to etch the insulation layer 180 exposed by a plurality of fourth openings through the plurality of fourth openings, so as to remove parts of the insulation layer 180 and form grooves extending along the second direction Y.

A chemical vapor deposition, physical vapor deposition, atomic layer deposition, or any combination of these thin film deposition processes may be used to deposit a conductive material in the grooves to form the bit line 130.

In this way, the bit line 130 may be configured to control the on and off of a single transistor structure when word line 120 is selected for a column of transistor structures, thereby enabling a single DRAM cell to perform read or write operations on data.

Herein, in an example, in the scenario of projecting along the third direction Z, the projection of the formed bit line 130 may be between the projections of two adjacent columns of channel structures 110. Moreover, there may be projections of two columns of channel structures 110 between the projections of two adjacent bit lines 130 when the number of bit lines 130 is multiple.

In this way, when one bit line 130 is connected to two columns of channel structures 110, the distance between the bit line 130 and the two columns of channel structures 110 connected to the bit line 130 may be shortened, thereby simplifying the wiring connection structure and reducing wiring losses. Moreover, by reasonably setting the width of the bit line 130 in the first direction X, the bit line 130 may be in contact with both of the two adjacent channel structures 110, thereby realizing the connection between a single bit line 130 and two adjacent columns of channel structures 110, and simplifying the semiconductor structure 100, and thus reducing the height of the semiconductor structure 100 in the third direction Z and achieving further miniaturization of the semiconductor structure 100 in size.

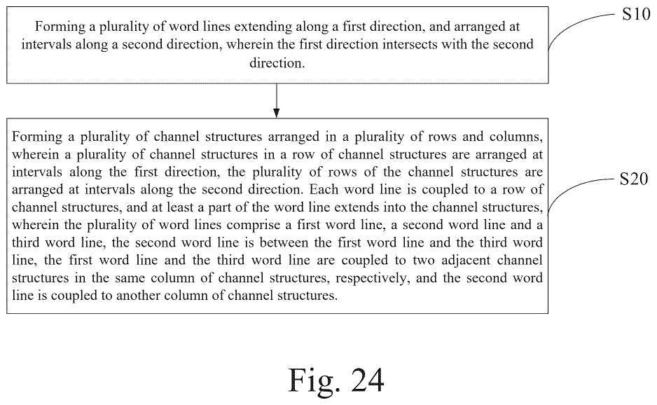

FIG. 24 is a flowchart of a manufacturing method of a semiconductor structure 100 in the context of a CAA transistor, provided by some implementations of the present disclosure.

As shown in FIG. 24, in some implementations, the manufacturing method of semiconductor structure 100 includes the following operations S10 to S20.

S10: Forming a plurality of word lines extending along a first direction, and arranged at intervals along a second direction, wherein the first direction intersects with the second direction.

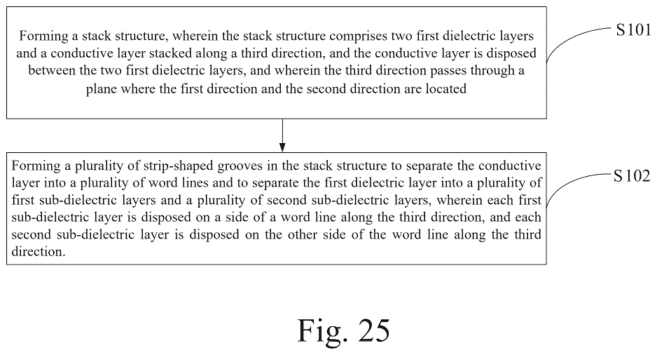

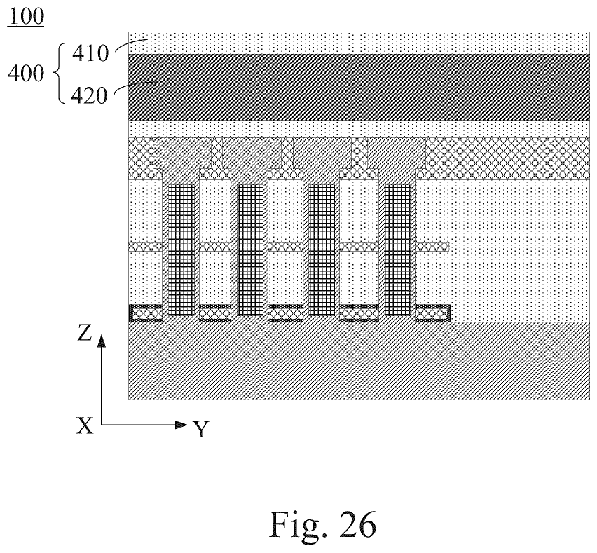

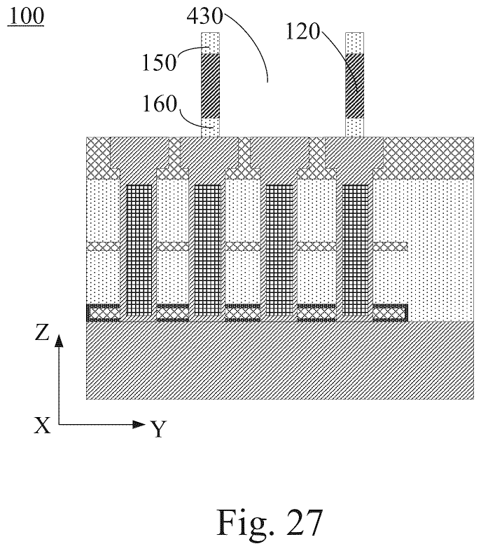

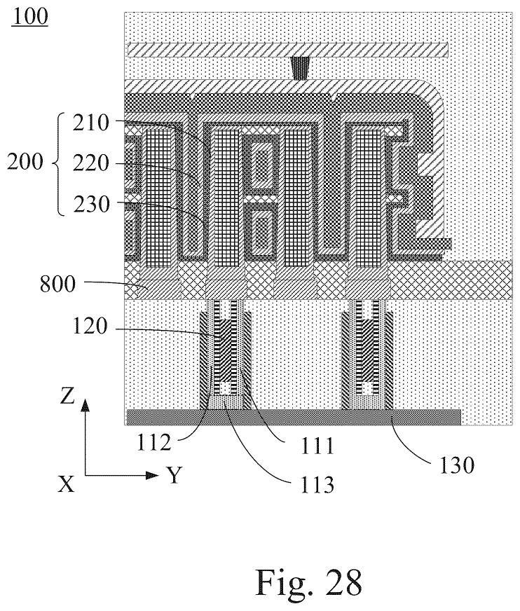

FIG. 25 is a flowchart of a manufacturing method of a word line 120 in the context of a CAA transistor, provided by some implementations of the present disclosure. FIG. 26 is a structural schematic diagram of a semiconductor structure 100 corresponding to the manufacturing method in FIG. 25. FIG. 27 is a structural schematic diagram of another semiconductor structure 100 corresponding to the manufacturing method in FIG. 25. FIG. 28 is a structural schematic diagram of yet another semiconductor structure 100 corresponding to the manufacturing method in FIG. 25;

As shown in FIG. 25, the operation S10 described above may also include the following operations S101-102.

S101: Forming a stack structure, wherein the stack structure comprises two first dielectric layers and a conductive layer stacked along a third direction, and the conductive layer is disposed between the two first dielectric layers, and wherein the third direction passes through a plane where the first direction and the second direction are located.

In operation S101, a chemical vapor deposition, physical vapor deposition, atomic layer deposition, or any combination of these thin film deposition processes may be used to form two first dielectric layers 410 and a conductive layer 420, thereby forming a stack structure 400 as shown in FIG. 26.

Herein, the material of the first dielectric layer 410 may include an insulating material. In an example, the insulating material may include one or more of an oxide material (such as silicon oxide), nitride material (such as silicon nitride), and oxynitride material (such as silicon oxynitride), which is not limited by implementations of the present disclosure. In this implementation, the insulating material constituting the first dielectric layer 410 may include silicon oxide.

The material of conductive layer 420 may include a conductive material. In an example, the conductive material may include W, Co, Cu, Al, doped silicon, silicide, or any combination thereof, which is not limited by implementations of the present disclosure. In this implementation, the conductive material constituting the conductive layer 420 may include wolfram.

S102: Forming a plurality of strip-shaped grooves in the stack structure to separate the conductive layer into a plurality of word lines and to separate the first dielectric layer into a plurality of first sub-dielectric layers and a plurality of second sub-dielectric layers, wherein each first sub-dielectric layer is disposed on a side of a word line along the third direction, and each second sub-dielectric layer is disposed on the other side of the word line along the third direction.

In an example, in this operation S102, suitable processes such as static spin coating or dynamic spray coating, etc. may be used to form a photoresist layer on the surface of a side of the first dielectric layer, and the photoresist layer may be patterned to obtain a fifth mask layer with a plurality of fifth openings.

As shown in FIGS. 26 and 27, in this implementation, any suitable process such as SADP may be used to etch the stack structure 400 exposed by a plurality of fifth openings, so as to remove parts of the stack structure 400 to form a plurality of strip-shaped grooves 430 that run through the stack structure along the third direction Z. Herein, the plurality of strip-shaped grooves 430 may be arranged at intervals along the second direction Y, so as to use a plurality of strip-shaped grooves 430 to separate the conductive layer 420 into a plurality of word lines 120.

Herein, in an example, since the stack structure 400 is formed by stacking two first dielectric layers 410 and a conductive layer 420, the first dielectric layers 410 on both sides of the strip grooves 430 in the third direction Z will also be separated into a plurality of first sub-dielectric layers 150 and a plurality of second sub-dielectric layers 160 by a plurality of strip grooves 430 when a plurality of strip grooves 430 separate the conductive layer 420 into a plurality of word lines 120.

Herein, the first sub-dielectric layer 150 is disposed on a side of the word line 120 along the third direction Z, and the second sub-dielectric layer 160 is disposed on the other side of the word line 120 along the third direction Z.

In this operation S102, by manufacturing the plurality of word lines 120, a column of channel structures connected to a single word line 120 may be selected by using the word lines 120 when the manufacturing process of the plurality of channel structures 110 is completed in the subsequent manufacturing, so as to achieve the on/off control of a single channel structure 110 in connection with the subsequently manufactured the bit lines 130 (see FIG. 8), and then to control the charging and discharging of the capacitor unit 200 (see FIG. 8) by using the channel structures 110, thereby realizing the read, write, or erase operations of data of the constituted DRAM cell.

Moreover, when manufacturing of the channel structure 110 is completed subsequently, both ends of the channel structure 110 in the third direction Z need to be in contact with the capacitor unit 200 or the bit line 130, and therefore, in this operation S102, by forming the first sub-dielectric layer 150 and the second sub-dielectric layer 160, the isolation between the word line 120 and the capacitor unit 200 or the connection 113 (see FIG. 8) may be achieved by using the first sub-dielectric layer 150 and the second sub-dielectric layer 160, thereby avoiding contact between the word line 120 and the capacitor unit 200 or the connection 113, and improving the reliability of the semiconductor structure 100.

Moreover, in some examples, the manufacturing process of the word line 120 may be performed before the manufacturing of the channel structure 110, so as to reduce the limitation on the material of the channel structure 110. In an example, the material of the channel structure 110 may include a low-temperature material such as IGZO. In this way, a heat treatment process may be performed on the metal material of the word line 120 to remove the redundant impurities in the word line 120 material, thereby improving the material purity of the word line 120, reducing the resistance of the manufactured word line 120, and reducing the device loss of the manufactured semiconductor structure 100.

In some other examples, the manufacturing process of the word line 120 may also be performed after the manufacturing of the channel structure 110, which is not limited by implementations of the present disclosure.

S20: Forming a plurality of channel structures arranged in a plurality of rows and columns, wherein a plurality of channel structures in a row of channel structures are arranged at intervals along the first direction, the plurality of rows of channel structures are arranged at intervals along the second direction. Each word line is coupled to a row of channel structures, and at least a part of the word line extends into the channel structures, wherein the plurality of word lines comprise a first word line, a second word line and a third word line, the second word line is between the first word line and the third word line, the first word line and the third word line are coupled to two adjacent channel structures in the same column of channel structures, respectively, and the second word line is coupled to another column of channel structures.

Please continue to refer to FIG. 6. In practical applications, the position of the manufactured word line 120 corresponding to a single channel structure 110 in a row of channel structures 110 may be used as a gate corresponding to the single channel structure 110 in the row of channel structures 110. Based on this, as a feasible implementation, when a portion of the word line 120 corresponding to a single channel structure 110 serves as a gate, the portion and the channel structure 110 may constitute a transistor structure.

Herein, the manufactured plurality of channel structures 110 is in the layout. The plurality of word lines 120 include a first word line 121, a second word line 122, and a third word line 123, wherein the second word line 122 is between the first word line 121 and the third word line 123, the first word line 121 and the third word line 123 are coupled to two adjacent channel structures 110 in the same column of channel structures 110, respectively, and the second word line 122 is coupled to another column of channel structures 110.

In this way, a staggered arrangement between two adjacent columns of channel structures 110 may be achieved when the manufactured plurality of channel structures 110 are arranged in a plurality of columns.

Moreover, in this implementation, by arranging the manufactured two adjacent columns of channel structures 110 in a staggered manner, a hexagonal arrangement between a plurality of channel structures 110 may be achieved when the channel structures 110 are in a plurality of columns.

In this way, the device density among a plurality of channel structures 110 may be increased and the layout area of the semiconductor structure 100 occupied by a plurality of channel structures 110 may be reduced when the number of channel structures 110 is not changed.

Moreover, in some examples, due to the hexagonal arrangement among a plurality of channel structures 110 in implementations of the present disclosure, if the layout of a plurality of capacitor units 200 (see FIG. 8) in the capacitor structure layer connected to a plurality of channel structures 110 also adopts a hexagonal arrangement, a plurality of channel structures 110 may be directly connected to a plurality of capacitor units when manufacturing a DRAM cell array. That is to say, each channel structure 110 may be directly connected to a capacitor unit without the need for an additional transition structure (such as a connection contact, etc.) to be manufactured between the two.

In this way, the semiconductor structure 100 may be simplified, and the height of the semiconductor structure 100 in the third direction Z may be reduced, thereby increasing the device density of the semiconductor structure 100 and facilitating further miniaturization of the semiconductor structure 100 in size.

Moreover, in some other examples, the layout of a plurality of capacitor units 200 in the capacitor structure layer connected to a plurality of channel structures 110 may also adopt other forms, and the connection between a plurality of channel structures 110 and a plurality of capacitor units 200 may also be achieved through an transition structure 800 as shown in FIG. 28, which is not limited by implementations of the present disclosure.

Please continue to refer to FIG. 6. Since at least a part of the word line 120 extends into the channel structure 110, the channel structure 110 may be separated by the word line 120 into a first sub-channel 111 and a second sub-channel 112, wherein the first sub-channel 111 is disposed on a side of the word line 120 along the second direction Y, and the second sub-channel 112 is disposed on the other side of the word line 120 along the second direction Y, and wherein the first sub-channel 111 and the second sub-channel 112 both extend along the third direction Z.

In this way, the first and second sub-channels 111 and 112 may be utilized to increase the facing area between the entire channel structure 110 and the word line 120, thereby improving the control accuracy of the word line 120 on CAA transistor structures subsequently manufactured based on the channel structure 110.

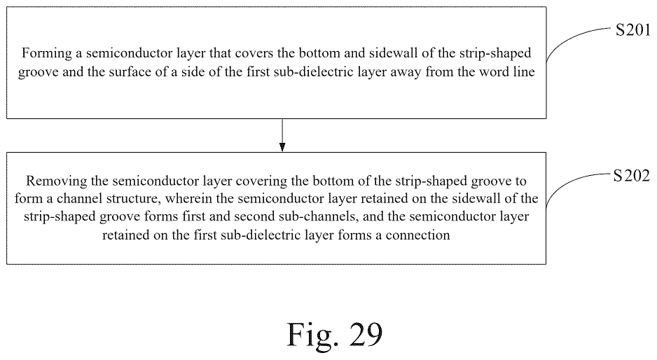

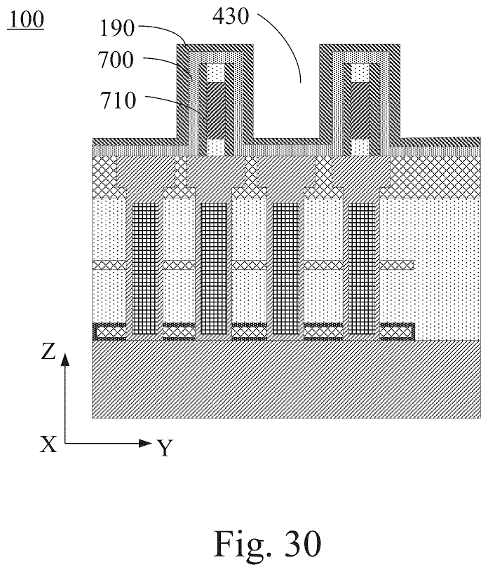

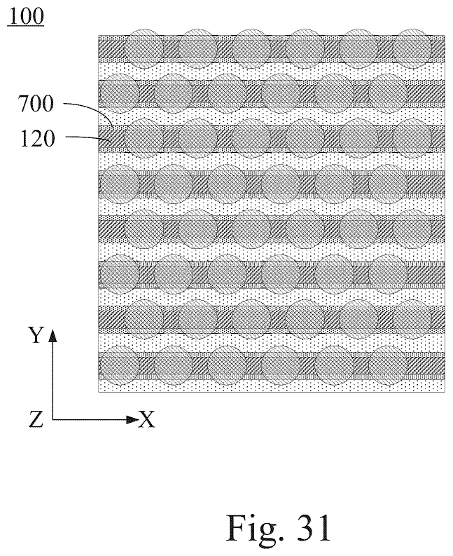

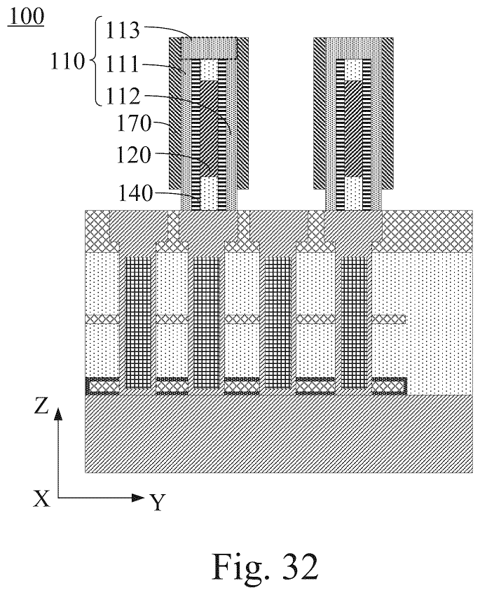

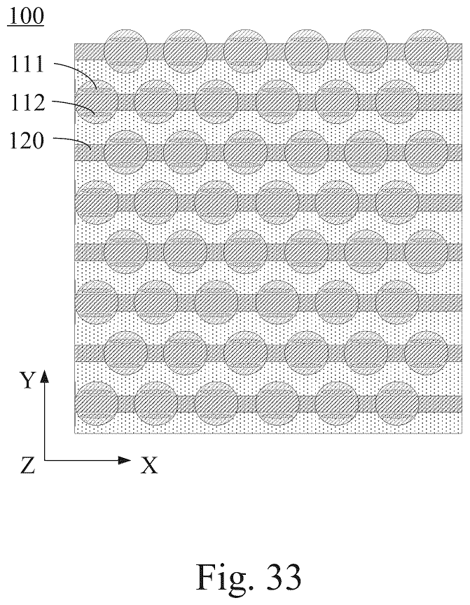

FIG. 29 is a flowchart of a manufacturing method of a channel structure 100 in the context of a CAA transistor, provided in some implementations of the present disclosure. FIG. 30 is a structural schematic diagram of a semiconductor structure 100 corresponding to the manufacturing method in FIG. 29. FIG. 31 is a schematic diagram of a film layer of a semiconductor structure 100 corresponding to the manufacturing method in FIG. 29. FIG. 32 is a structural schematic diagram of another semiconductor structure 100 corresponding to the manufacturing method in FIG. 29. FIG. 33 is a schematic diagram of a film layer corresponding to the semiconductor structure 100 in FIG. 32.

As shown in FIG. 29, in some implementations, the operation S20 described above may also include the following operations S201-S202.

S201: Forming a semiconductor layer that covers the bottom and sidewall of the strip-shaped groove and the surface of a side of the first sub-dielectric layer away from the word line.

As shown in FIGS. 30 and 31, in this operation S201, a chemical vapor deposition, physical vapor deposition, atomic layer deposition, or any combination of these thin film deposition processes may be used to deposit a semiconductor material in the strip-shaped groove 430 to form the semiconductor layer 700.

Herein, in an example, a semiconductor material may include IGZO, silicon, doped silicon, germanium, or any other suitable material, which is not limited by implementations of the present disclosure. For example, in this implementation, the material of the semiconductor layer 700 may include an oxide semiconductor material, such as IGZO.

In this way, the channel structure manufactured using the semiconductor layer 700 may have a smaller leakage current, thereby prolonging the data storage time of DRAM cells and reducing the device loss of the semiconductor structure 100. Moreover, due to the higher carrier mobility of IGZO, under the same requirements, the size of the manufactured channel structure may be reduced by using IGZO, which is beneficial for the miniaturization of semiconductor structure 100.

S202: Removing the semiconductor layer covering the bottom of the strip-shaped groove to form a channel structure, wherein the semiconductor layer retained on the sidewall of the strip-shaped groove forms first and second sub-channels, and the semiconductor layer retained on the first sub-dielectric layer forms a connection.

In this operation S202, any suitable process such as dry etching or wet etching, etc. may be used to remove the semiconductor layer 700 covering the bottom of the strip-shaped groove 430, to obtain the semiconductor structure shown in FIGS. 32 and 33.

Herein, the semiconductor layer retained on the sidewall of the strip-shaped groove forms the first and second sub-channels 111 and 112, and the semiconductor layer retained on the first sub-dielectric layer forms the connection 113.

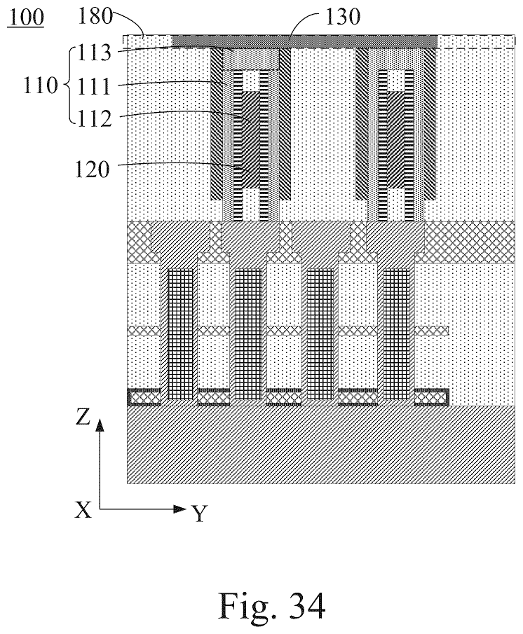

In this way, the connection 113 may be configured to connect the first sub-channel 111, the second sub-channel 112, and the bit line 130 (see FIG. 34), thereby increasing the contact area between the channel structure 110 and the bit line 130, reducing the contact resistance, and reducing the device loss of the semiconductor structure 100. Moreover, the manufacturing of the connection 113 may further improve the alignment accuracy between the bit line 130 and the channel structure 110, thereby reducing the difficulty of the manufacturing process of the bit line 130.

Please continue to refer to FIGS. 30 and 32. In some implementations, when the material of the channel structure 110 includes IZGO, the manufacturing method of the semiconductor structure 100 further includes the following operations S41-S42.

S41: Forming an initial dielectric layer 190 that covers the surface of a side of the semiconductor layer 700.

In this operation S41, a chemical vapor deposition, physical vapor deposition, atomic layer deposition, or any combination of these thin film deposition processes may be used to deposit a dielectric material on the surface of a side of the semiconductor layer to form the initial dielectric layer 190.

S42: Removing a part of the initial dielectric layer 190 to form a second dielectric layer 170.

In this operation S42, any suitable process such as dry etching or wet etching, etc. may be used to remove the initial dielectric layer 190 covered on the semiconductor layer at the bottom of the groove and parts of the sidewall and the initial dielectric layer 190 covered on the semiconductor layer on the surface of a side of the first sub-dielectric layer away from the word line, so as to form the second dielectric layer 170.

In an example, the material of the second dielectric layer 170 may include any suitable high dielectric constant (high-K) material such as aluminum oxide, chromium oxide, zirconium oxide, etc., which is not limited by implementations of the present disclosure.

In this way, the good compatibility between a high-K material and IGZO may be utilized to achieve coverage of the first and second sub-channels 111 and 112, thereby avoiding oxidation of the first and second sub-channels 111 and 112.

FIG. 34 is a structural schematic diagram of yet another semiconductor structure 100 corresponding to a manufacturing method provided in implementations of the present disclosure.

After completing the manufacturing of the channel structure 110 in the afore-mentioned operation S202, the manufacturing method of the semiconductor structure 100 may further include the following operation S203.

S203: Forming a bit line 130, wherein the bit line 130 is formed on a side of the connection 113 away from the word line 120 along the third direction Z, extends along the second direction Y, and is connected to the connection 113 of both adjacent columns of channel structures 110, and wherein the third direction Z passes through the plane where the first direction X and the second direction Y are located.

As shown in FIG. 34, for example, in this operation S203, a chemical vapor deposition, physical vapor deposition, atomic layer deposition, or any combination of these thin film deposition processes may be used to deposit an insulating material on a side of the connection 113 in the third direction Z to form an insulating layer 180.

In an example, suitable processes such as static spin coating or dynamic spray coating, etc. may be used to form a photoresist layer on the surface of a side of the insulating layer 180, and the photoresist layer may be patterned to obtain a sixth mask layer with a plurality of sixth openings.

Any suitable etching process such as dry etching or wet etching, etc. is used to etch the insulation layer 180 exposed by a plurality of sixth openings through the plurality of sixth openings to remove a part of the insulation layer 180 and form a groove extending along the second direction Y, wherein the groove exposes the connection 113 of two adjacent columns of channel structures 110.

A chemical vapor deposition, physical vapor deposition, atomic layer deposition, or any combination of these thin film deposition processes is used to deposit a conductive material in the grooves to form the bit line 130.

In this way, the bit line 130 may be configured to control the on and off of a single transistor structure when the word line 120 is selected for a column of transistor structures, thereby enabling a single DRAM cell to perform read or write operations on data.

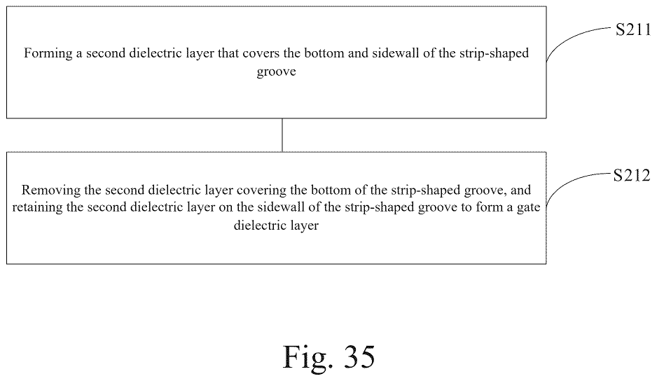

FIG. 35 is a flowchart of a manufacturing method of a gate dielectric layer 140 in the context of a CAA transistor, provided by some implementations of the present disclosure.

As shown in FIG. 35, in some implementations, before the afore-mentioned operation S201, the manufacturing method of the semiconductor structure 100 may further include the following operations S211-S212.

S211: Forming a second dielectric layer that covers the bottom and sidewall of the strip-shaped groove.

Please continue to refer to FIG. 30. In this operation S211, a chemical vapor deposition, physical vapor deposition, atomic layer deposition, or any combination of these thin film deposition processes may be used to form the second dielectric layer 710 in the strip-shaped groove 430.

Herein, in an example, the material of the second dielectric layer 710 may include one or more of an oxide material (such as silicon oxide), nitride material (such as silicon nitride), and oxynitride material (such as silicon oxynitride). Alternatively, the material of the gate dielectric layer 140 may also include any suitable high dielectric constant (high-K) material such as aluminum oxide, chromium oxide, zirconium oxide, etc., which is not limited by implementations of the present disclosure.

S212: Removing the second dielectric layer covering the bottom of the strip-shaped groove, and retaining the second dielectric layer on the sidewall of the strip-shaped groove to form a gate dielectric layer.

In this operation S212, any suitable process such as dry etching or wet etching, etc. may be used to remove the second dielectric layer 710 covering the bottom of the strip-shaped groove 430, so as to form the gate dielectric layer 140 as shown in FIG. 32.

In this implementation, by disposing the gate dielectric layer 140 between the channel structure 110 and the word line 120, isolation between the channel structure 110 and the word line 120 may be achieved, thereby avoiding direct current conduction between the channel structure 110 and the word line 120.

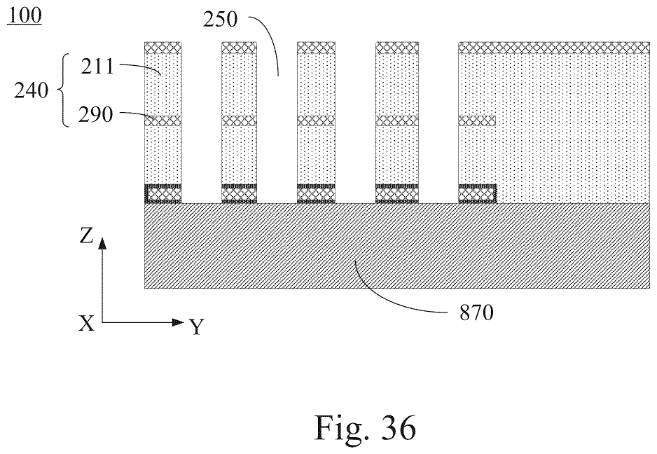

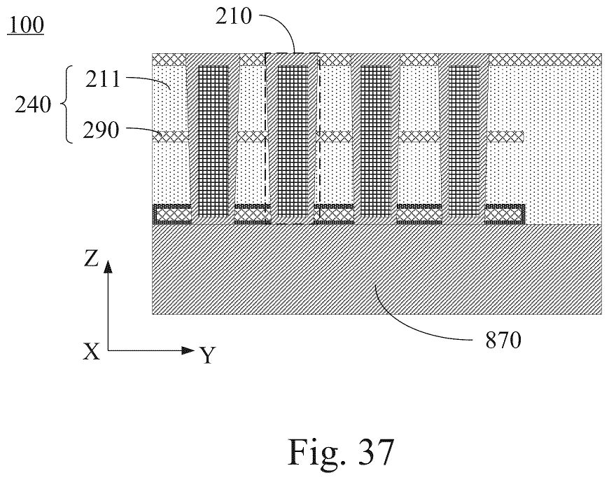

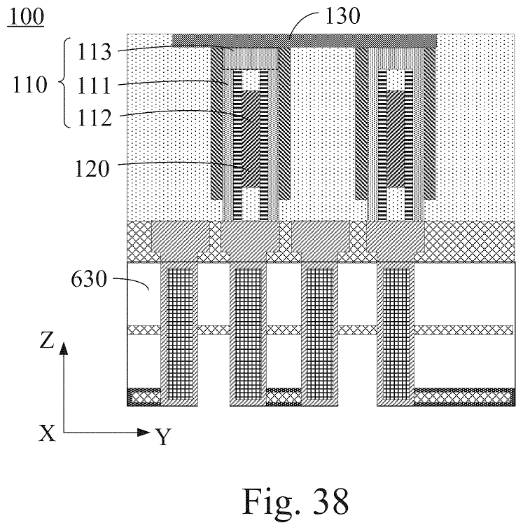

FIG. 36 is a structural schematic diagram of yet another semiconductor structure 100 corresponding to a manufacturing method, provided in implementations of the present disclosure. FIG. 37 is a structural schematic diagram of yet another semiconductor structure 100 corresponding to a manufacturing method, provided in implementations of the present disclosure. FIG. 38 is a structural schematic diagram of yet another semiconductor structure 100 corresponding to a manufacturing method, provided in implementations of the present disclosure.

In some implementations, before the afore-mentioned operations S11 and S101, the manufacturing method of semiconductor structure 100 may further include the following operation S100.

S100: Forming the first electrode 210.

As shown in FIG. 36, for example, in this operation S100, a chemical vapor deposition, physical vapor deposition, atomic layer deposition, or any combination of these thin film deposition processes may be used to alternately stack a plurality of support layers 290 and a plurality of sacrificial layers 212 on the substrate 870 to form a stacked layer 240.

In an example, the substrate 870 may be a single crystal silicon (Si) substrate, a single crystal germanium (Ge) substrate, a silicon on insulator (SOI) substrate, or a germanium on insulator (GOI) substrate, etc. Alternatively, the material of the substrate 870 may also include a compound semiconductor. In an example, the substrate 870 may be a gallium arsenide (GaAs) substrate, indium phosphide (InP) substrate, or silicon carbide (SiC) substrate, etc. Alternatively, the substrate 870 may also be made of other semiconductor materials commonly used in this field, which is not limited by implementations of the present disclosure.

In this implementation, the substrate 870 may provide support force for the manufacturing of the stacked layer 240, and in an example, the substrate 870 may be removed in subsequent manufacturing processes, so as to achieve the manufacturing of other processes on the exposed stacked layer 240.

Moreover, “alternately stack” refers to the formation of a support layer 211, followed by the formation of a sacrificial layer 212 on the support layer 211, and then the formation of a support layer 211 on the sacrificial layer 212, and so on. Herein, the thickness of a plurality of support layers 211 may be the same or different, and the thickness of a plurality of sacrificial layers 212 may be the same or different. The thickness of the support layer 211 and the sacrificial layer 212 may be set according to specific process requirements. In practical applications, the sacrificial layer 212 may be removed and replaced with other materials in subsequent processes.

As a feasible implementation, in this operation S100, a photoresist layer may be formed on the surface of a side of the stacked layer 240 and patterned to obtain a third mask layer with a plurality of third openings. The stacked layer 240 is etched based on the third mask layer to form a plurality of second through-holes 250. In an example, a dry etching may be used to etch the stacked layer 240 to obtain a plurality of second through-holes 250.

CVD, PVD, ALD or any combination of these thin film deposition processes is used to deposit a conductive material in the second through-hole 250 to form the first electrode 210 as shown in FIG. 37. In an example, the conductive material may include a combination of one or more of wolfram, cobalt, copper, aluminum, and metal silicide, or other suitable materials.

In practical applications, during the deposition of the first electrode 210, there may be excess conductive material covering the surface of a side of the stacked layer 240. Therefore, chemical mechanical polishing (CMP) may be used to grind the excess conductive material to remove the excess conductive material covering the surface of a side of the stacked layer 240, to obtain the first electrode 210 in the second through-hole 250 as shown in FIG. 37, so that the subsequently manufactured channel structure 110 may be connected to the first electrode 210.

Please continue to refer to FIG. 37. In some examples, since the manufacturing process of the second through-hole 250 mostly adopts any suitable etching process such as dry etching or wet etching, etc., as the etching depth in the third direction Z increases, the width of the manufactured second through-hole 250 will gradually decrease as the etching depth increases, resulting in a gradual decrease in the size of the first electrode 210 manufactured in the second through-hole 250 in the first direction X. Therefore, after completing the manufacturing of the channel structure 110 subsequently, in the third direction Z, the size of the end of the first electrode 210 close to the channel structure 110 may be larger than the size of the end of the first electrode 210 away from the channel structure 110.

In some implementations, after the afore-mentioned operations S2 and S20, the manufacturing method of the semiconductor structure 100 may further include the following operation S3.

S3: Forming the second electrode 220 and the first dielectric layer 230 to form the capacitor unit 200.

As shown in FIGS. 37 and 38, in this operation S3, after completing the manufacturing of the afore-mentioned channel structure 110, a process such as CMP may be used to grind the substrate 870 to remove the substrate 870 and expose the stacked layer 240. In an example, a photoresist layer may be formed on the surface of a side of the stacked layer 240 away from the channel structure 110, and patterned to obtain a fourth mask layer with a plurality of fourth openings. The stacked layer 240 is etched based on the fourth mask layer to form a plurality of holes. In an example, a dry etching may be used to etch the stacked layer 240 to obtain a plurality of holes.

In this operation S3, the sacrificial layer 212 may be removed through holes to form a gap 630 and expose the first electrode 210. In an example, similarly, any suitable process such as dry etching or wet etching, etc. may be used to remove the sacrificial layer 212. For example, in one implementation, concentrated sulfuric acid immersion may be used to corrode each sacrificial layer 212 to form the gap 630.

As a feasible implementation, epitaxial growth process may be used to form the first dielectric layer 230 shown in FIGS. 13 and 14 on the sidewall of the first electrode 210 through the gap 630, thereby achieving insulation between the first electrode 210 and the subsequently formed second electrode 220 (please continue to refer to FIGS. 13 and 14) by using the first dielectric layer 230.

Moreover, CVD, PVD, ALD or any combination of these thin film deposition processes may be used to deposit a conductive material in the gap 630 to form the second electrode 220, thereby constituting the capacitor unit 200 together with the afore-mentioned first dielectric layer 230 and first electrode 210 (please continue to refer to FIGS. 13 and 14).

In an example, a conductive material may include a combination of one or more of wolfram, cobalt, copper, aluminum, and metal silicide, or other suitable materials. Herein, in this implementation, the material of the second electrode 220 may include germanium silicon, which has a relatively small material stress. During the process of filling the gap, the stress generated on the columnar structure of the first electrode 210 is relatively small, which may reduce the impact on the structural stability of the first electrode 210, thereby ensuring the stability of the first electrode 210, avoiding the occurrence of bending of the columnar structure of the first electrode 210, and improving the stability and reliability of the manufactured semiconductor structure 100. The above are only specific implementations of the present disclosure, but the protection scope of the present disclosure is not limited to this. Any variations or alternatives that may be easily conceived by those skilled in the art within the scope of the technology disclosed in the present disclosure should be included in the protection scope of the present disclosure. Accordingly, the protection scope of the present disclosure is to be determined by the scope of the claims.

What is claimed is:

1. A semiconductor structure, comprising:
a plurality of channel structures arranged in a plurality of rows and a plurality of columns, wherein channel structures in a row of the plurality of rows are arranged at intervals along a first direction, the plurality of rows are arranged at intervals along a second direction, and the first direction intersects with the second direction; and
a plurality of word lines extending along the first direction, the plurality of word lines being arranged at intervals along the second direction and each coupled to a respective row of channel structures,
wherein the plurality of word lines comprise a first word line, a second word line, and a third word line, the second word line is between the first word line and the third word line, the first word line and the third word line are respectively coupled to two adjacent channel structures in a same column of channel structures, and the second word line is coupled to another column of channel structures.

2. The semiconductor structure of claim 1, further comprising:
a plurality of bit lines extending along the second direction, the plurality of bit lines being arranged at intervals along the first direction, wherein two corresponding adjacent columns of channel structures are connected to a same bit line.

3. The semiconductor structure of claim 2, wherein the bit line is disposed at a side of a channel structure along a third direction and is connected with ends of the two corresponding adjacent columns of channel structures at the side, wherein the third direction passes through a plane where the first direction and the second direction are located.

4. The semiconductor structure of claim 1, wherein a channel structure runs through a word line along a third direction, wherein the third direction passes through a plane where the first direction and the second direction are located, and
wherein in the third direction, the channel structure comprises a first end and a second end disposed opposite to each other, and each of a size of the first end in the second direction and a size of the second end in the second direction is smaller than or equal to a size of the word line in the second direction.

5. The semiconductor structure of claim 4, wherein a size of the channel structure in the second direction is smaller than or equal to a size of the channel structure in the first direction.

6. The semiconductor structure of claim 4, wherein, in the third direction, both ends of the channel structure protrude from the word line.

7. The semiconductor structure of claim 4, wherein a material of the channel structure includes an oxide semiconductor material.

8. The semiconductor structure of claim 4, further comprising:
a gate dielectric layer between the channel structure and the word line.

9. The semiconductor structure of claim 2, further comprising:
a plurality of capacitor units arranged in rows and columns,
wherein a capacitor unit is disposed at an end of a channel structure away from the bit line and is connected with the end of the channel structure away from the bit line, and wherein, in a direction parallel to a plane where the first direction and the second direction are located, the capacitor unit comprises a first side and a second side located on two sides of the channel structure in the direction, respectively.

10. The semiconductor structure of claim 9, wherein the capacitor unit disposed at the end of the channel structure away from the bit line is in contact with the end of the channel structure away from the bit line.

11. The semiconductor structure of claim 9, wherein the capacitor unit comprises a first electrode, a second electrode and a first dielectric layer,
wherein the first electrode extends along a third direction and is connected with the end of the channel structure away from the bit line, the second electrode surrounds at least a part of the first electrode, the first dielectric layer is between the first electrode and the second electrode, and the third direction passes through the plane where the first direction and the second direction are located, and
wherein, in the third direction, a size of an end of the first electrode close to the channel structure is greater than a size of an end of the first electrode away from the channel structure.

12. The semiconductor structure of claim 9, wherein the first direction is perpendicular to the second direction, and
wherein a ratio of a distance between two adjacent word lines to a distance between two adjacent capacitor units is greater than or equal to 0.25 and less than or equal to 0.9, and a ratio of a distance between two adjacent bit lines to a distance between two adjacent capacitor units is greater than or equal to 0.5 and less than or equal to 1.9.

13. The semiconductor structure of claim 9, further comprising:
an interconnection layer located at a side of a memory array including the plurality of channel structures and the plurality of capacitor units in a third direction, wherein the interconnection layer includes a first connection structure, a second connection structure, and a third connection structure, and the third direction passes through the plane where the first direction and the second direction are located, and
wherein the first connection structure is connected with the bit line, a part of the second connection structure extends into the memory array and is connected with the word line, and a part of the third connection structure extends into the memory array and is connected with the capacitor unit, or the first connection structure is connected with the capacitor unit, a part of the second connection structure extends into the memory array and is connected with the bit line, and a part of the third connection structure extends into the memory array and is connected with the word line.

14. The semiconductor structure of claim 13, further comprising:
a peripheral device stacked on a side of the interconnect layer away from the memory array and coupled to the memory array through the interconnect layer.

15. A manufacturing method of a semiconductor structure, comprising:
forming a plurality of word lines extending along a first direction, the plurality of word lines being arranged at intervals along a second direction, wherein the first direction intersects with the second direction; and
forming a plurality of channel structures arranged in a plurality of rows and a plurality of columns,
wherein channel structures in a row of the plurality of rows are arranged at intervals along the first direction, the plurality of rows are arranged at intervals along the second direction, and each word line is coupled to a respective row of channel structures, and
wherein the plurality of word lines comprise a first word line, a second word line, and a third word line, the second word line is between the first word line and the third word line, the first word line and the third word line are respectively coupled to two adjacent channel structures in a same column of channel structures, and the second word line is coupled to another column of channel structures.

16. The manufacturing method of claim 15, wherein forming the plurality of word lines comprises:
forming a stack structure, wherein the stack structure comprises two first dielectric layers and a conductive layer stacked along a third direction, and the conductive layer is disposed between the two first dielectric layers, and wherein the third direction passes through a plane where the first direction and the second direction are located; and
forming a plurality of strip-shaped grooves in the stack structure to separate the conductive layer into the plurality of word lines, wherein the plurality of strip-shaped grooves extend along the first direction and run through the stack structure along the third direction, and the plurality of strip-shaped grooves are arranged at intervals along the second direction.

17. The manufacturing method of claim 16, wherein, before forming the plurality of channel structures, the manufacturing method further comprises:
forming a plurality of first through-holes in the stack structure, wherein the plurality of first through-holes run through the stack structure along the third direction, and are arranged in a plurality of rows and columns, a plurality of the first through-holes in a row of the first through-holes are arranged at intervals along the first direction, and the plurality of rows of the first through-holes are arranged at intervals along the second direction, and wherein a strip-shaped groove is formed between two adjacent rows of first through-holes.

18. The manufacturing method of claim 17, wherein forming the plurality of channel structures comprises:
forming a semiconductor material within the first through-holes to form the plurality of channel structures.

19. The manufacturing method of claim 15, further comprising:
forming a bit line, wherein the bit line is formed at an end of the channel structure along a third direction, extends along the second direction, and is connected with ends of two adjacent columns of channel structures, and wherein the third direction passes through a plane where the first direction and the second direction are located.

20. A memory system, comprising:
a semiconductor structure, comprising:
a plurality of channel structures arranged in a plurality of rows and a plurality of columns, wherein channel structures in a row of the plurality of rows are arranged at intervals along a first direction, the plurality of rows are arranged at intervals along a second direction, and the first direction intersects with the second direction; and
a plurality of word lines extending along the first direction, the plurality of word lines being arranged at intervals along the second direction and each coupled to a respective row of channel structures, wherein the plurality of word lines comprise a first word line, a second word line and a third word line, the second word line is between the first word line and the third word line, the first word line and the third word line are respectively coupled to two adjacent channel structures in a same column of the channel structures, and the second word line is coupled to another column of channel structures; and
a controller coupled to the semiconductor structure and configured to control the semiconductor structure.
